(19) United States
(12) Patent Application Publication
(10) Pub. No.: US 2016/0379976 A1
(43) Pub. Date: Dec. 29, 2016

(54) SEMICONDUCTOR DEVICE AND METHOD FOR FABRICATING THE SAME

(71) Applicant: Samsung Electronics Co., Ltd., Suwon-si (KR)

(72) Inventor: Ju-Youn KIM, Suwon-si (KR)

(21) Appl. No.: 15/012,920

(22) Filed: Feb. 2, 2016

(30) Foreign Application Priority Data
Jun. 23, 2015 (KR) 10-2015-0088928

(51) Int. Cl. H01L 27/088; H01L 29/06

(52) U.S. Cl. CPC H01L 27/0886; H01L 29/0649

(57) ABSTRACT

A semiconductor device is provided. The semiconductor device includes a first fin-type pattern and a second fin-type pattern formed abreast in a lengthwise direction, a first trench formed between the first fin-type pattern and the second fin-type pattern, a field insulating film partially filling the first trench, an interlayer insulating film on the field insulating film, an insulating line pattern, and a conductive pattern. An upper surface of the field insulating film is lower than an upper surface of the first fin-type pattern and an upper surface of the second fin-type pattern. The interlayer insulating film covers the first fin-type pattern and the second fin-type pattern, and includes a second trench exposing the upper surface of the field insulating film. The second trench includes an upper portion and a lower portion. The insulating line pattern fills the lower portion of the second trench, and the conductive pattern fills the upper portion of the second trench.

### CROSS-REFERENCE TO RELATED APPLICATION

This application claims priority under 35 U.S.C. §119 to Korean Patent Application No. 10-2015-0088928, filed on Jun. 23, 2015, in the Korean Intellectual Property Office, the disclosure of which is incorporated herein by reference in its entirety.

### BACKGROUND

1. Technical Field

The present disclosure relates to a semiconductor device and a method for fabricating the same, and more particularly, to a semiconductor device comprising a fin-type pattern and a fabricating method thereof.

2. Description of the Related Art

For a semiconductor device density enhancement, a multigate transistor has been suggested as one of scaling technologies, by which a multi-channel active pattern (or silicon body) in a fin or nanowire shape is formed on a substrate, with gates formed on a surface of the multi-channel active pattern.

The multigate transistor allows easy scaling, as it uses a three-dimensional channel. Further, current control capability can be enhanced without requiring increased gate length of the multigate transistor. Furthermore, it is possible to effectively suppress short channel effect (SCE) which is a phenomenon that electric potential of the channel region is influenced by a drain voltage.

### SUMMARY

In accordance with an example embodiment of the present disclosure, a semiconductor device comprises a first fin-type pattern and a second fin-type pattern formed abreast in a lengthwise direction, a first trench formed between the first fin-type pattern and the second fin-type pattern, a field insulating film partially filling the first trench, an interlayer insulating film on the field insulating film, an insulating line pattern, and a conductive pattern. An upper surface of the field insulating film is lower than an upper surface of the first fin-type pattern and an upper surface of the second fin-type pattern. The interlayer insulating film covers the first fin-type pattern and the second fin-type pattern, and includes a second trench exposing the upper surface of the field insulating film. The second trench comprises an upper portion and a lower portion. The insulating line pattern fills the lower portion of the second trench. The conductive pattern fills the upper portion of the second trench.

In accordance with another example embodiment of the present disclosure, a semiconductor device comprises a first fin-type pattern and a second fin-type pattern formed abreast in a lengthwise direction, a trench formed between the first fin-type pattern and the second fin-type pattern, a field insulating film partially filling the trench, an insulating line pattern on the field insulating film, and a conductive pattern on the insulating line pattern. The insulating line pattern is formed between the first fin-type pattern and the second fin-type pattern. The conductive pattern is formed between the first fin-type pattern and the second fin-type pattern. A bottom surface of the conductive pattern is higher than the upper surface of the first fin-type pattern and the upper surface of the second fin-type pattern. The insulating line pattern does not contact the first fin-type pattern and the second fin-type pattern.

In accordance with further example embodiment of the present disclosure, a semiconductor device comprises a first fin-type pattern and a second fin-type pattern formed adjacent each other, a field insulating film partially surrounding the first fin-type pattern and the second fin-type pattern, and a gate pattern formed on the field insulating pattern, the first fin-type pattern, and the second fin-type pattern. The gate pattern comprises a first gate electrode intersecting the first fin-type pattern, a second gate electrode intersecting the second fin-type pattern, and a connect pattern connecting the first gate electrode and the second gate electrode. The connect pattern comprises an insulating line pattern formed on the field insulating film and a conductive pattern on the insulating line pattern.

### BRIEF DESCRIPTION OF THE DRAWINGS

The above and other objects, features and advantages of the present disclosure will become more apparent to those of ordinary skill in the art by describing in detail example embodiments thereof with reference to the accompanying drawings, in which:

FIGS. 1 and 2 are a layout diagram and a perspective view, respectively, provided to explain a semiconductor device according to a first example embodiment;

FIG. 3 is a partial perspective view provided to explain a fin-type pattern and a field insulating film of FIG. 2;

FIG. 4 is a cross sectional view taken on line A-A of FIG. 2, according to example embodiments;

FIGS. 5A and 5B are cross sectional views taken on line B-B of FIG. 2, according to example embodiments;

FIG. 6 is a view provided to explain a semiconductor device according to a second example embodiment;

FIG. 7 is a view provided to explain a semiconductor device according to a third example embodiment;

FIG. 8 is a view provided to explain a semiconductor device according to a fourth example embodiment;

FIG. 9 is a view provided to explain a semiconductor device according to a fifth example embodiment;

FIG. 10 is a view provided to explain a semiconductor device according to a sixth example embodiment;

FIG. 11 is a view provided to explain a semiconductor device according to a seventh example embodiment;

FIG. 12 is a layout diagram provided to explain a semiconductor device according to an eighth example embodiment;

FIG. 13 is a cross sectional view taken on line A-A of FIG. 12, according to example embodiments;

FIG. 14 is a cross sectional view taken on line C-C of FIG. 12, according to example embodiments;

FIG. 15 is a cross sectional view taken on line D-D of FIG. 12, according to example embodiments;

FIG. 16 is a view provided to explain a semiconductor device according to a ninth example embodiment;

FIGS. 17 to 27 are views illustrating intermediate stages of fabrication, provided to explain a method for fabricating a semiconductor device according to an example embodiment;

FIGS. 28 to 30 are views illustrating intermediate stages of fabrication, provided to explain a method for fabricating a semiconductor device according to another example embodiment;

FIG. 31 is a block diagram of an example system-on-chip (SoC) system comprising a semiconductor device according to example embodiments;

FIG. 32 is a block diagram of an electronic system comprising a semiconductor device according to example embodiments; and

FIGS. 33 to 35 illustrate example semiconductor systems which may apply therein a semiconductor device according to example embodiments.

### DETAILED DESCRIPTION OF THE EMBODIMENTS

Advantages and features of the present disclosed concepts and methods of accomplishing the same may be understood more readily by reference to the following detailed description of exemplary embodiments and the accompanying drawings. The present disclosed concepts may, however, be embodied in many different forms and should not be construed as being limited to the embodiments set forth herein. In the drawings, the thickness of layers and regions are exaggerated for clarity. Unless otherwise noted, like reference numerals in the drawings denote like elements, and thus their description will be omitted.

It will be understood that when an element or layer is referred to as being “on” or “connected to” another element or layer, it can be directly on or connected to the other element or layer or intervening elements or layers may be present. In contrast, when an element is referred to as being “directly on” or “directly connected to” another element or layer, or as “contacting” another element or layer, there are no intervening elements or layers present. As used herein, the term “and/or” includes any and all combinations of one or more of the associated listed items.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly. Also these spatially relative terms such as “above” and “below” as used herein have their ordinary broad meanings—for example element A can be above element B even if when looking down on the two elements there is no overlap between them (just as something in the sky is generally above something on the ground, even if it is not directly above). In addition, it will also be understood that when a layer is referred to as being “between” two layers, it can be the only layer between the two layers, or one or more intervening layers may also be present.

Terms such as “same,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to reflect this meaning.

The exemplary embodiments will be described with reference to cross-sectional views and/or plan views, which are ideal exemplary views. Thicknesses of layers and areas are exaggerated for effective description of the technical contents in the drawings. Forms of the embodiments may be modified by the manufacturing technology and/or tolerance. Therefore, the disclosed embodiments are not intended to be limited to illustrated specific forms, and may include modifications generated according to manufacturing processes. For example, an etching area illustrated at a right angle may be round or have a predetermined curvature. Therefore, areas illustrated in the drawings have overview properties, and shapes of the areas are illustrated special forms of the areas of a device, and are not intended to be limited to the scope of the disclosed embodiments.

The use of the terms “a” and “an” and “the” and similar referents in the context of describing the disclosed embodiments (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to”) unless otherwise noted.

It will be understood that, although the terms first, second, etc. may be used herein to describe various elements, these elements should not be limited by these terms. Unless the context indicates otherwise, these terms are only used to distinguish one element from another element. Thus, for example, a first element, a first component or a first section discussed below could be termed a second element, a second component or a second section without departing from the teachings of the disclosed embodiments.

The present disclosed embodiments will be described with reference to perspective views, cross-sectional views, and/or plan views, in which embodiments of the disclosure are shown. Thus, the profile of an example view may be modified according to manufacturing techniques and/or allowances. The embodiments are not intended to limit the scope of the present disclosure but cover all changes and modifications that can be caused due to a change in manufacturing process. Thus, regions shown in the drawings are illustrated in schematic form and the shapes of the regions are presented simply by way of illustration and not as a limitation.

Unless defined otherwise, all technical and scientific terms used herein have the same meaning as commonly understood by one of ordinary skill in the art to which the disclosed embodiments belong. It is noted that the use of any and all examples, or example terms provided herein is intended merely to better illuminate the embodiments and is not a limitation on the scope of the disclosure unless otherwise specified. Further, unless defined otherwise, all terms defined in generally used dictionaries may not be overly interpreted.

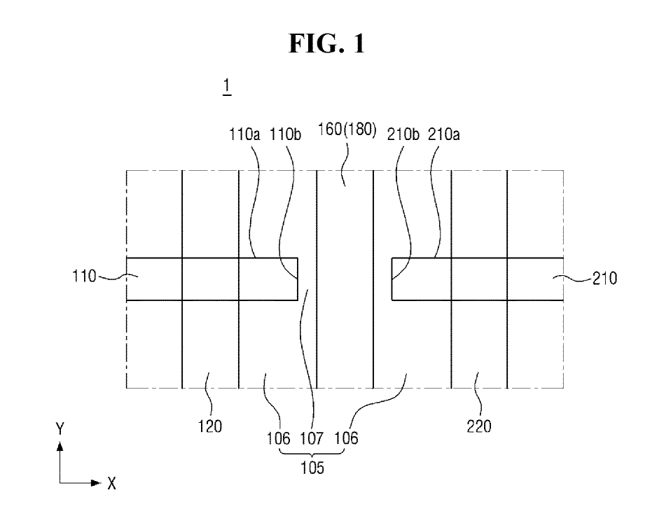

Hereinbelow, a semiconductor device according to the first example embodiment will be explained with reference to FIGS. 1 through 5B.

As used herein, a semiconductor device may refer to one or more transistors or logic devices formed on a semiconductor wafer, or a device such as a semiconductor chip (e.g., memory chip and/or logic chip formed on a die), a stack of semiconductor chips, a semiconductor package including one or more semiconductor chips stacked on a package substrate, or a package-on-package device including a plurality of packages. These devices may be formed using ball grid arrays, wire bonding, through substrate vias, or other electrical connection elements, and may include memory devices such as volatile or non-volatile memory devices.

An electronic device, as used herein, may refer to these semiconductor devices, but may additionally include products that include these devices, such as a memory module, a hard drive including additional components, or a mobile phone, laptop, tablet, desktop, camera, or other consumer electronic device, etc.

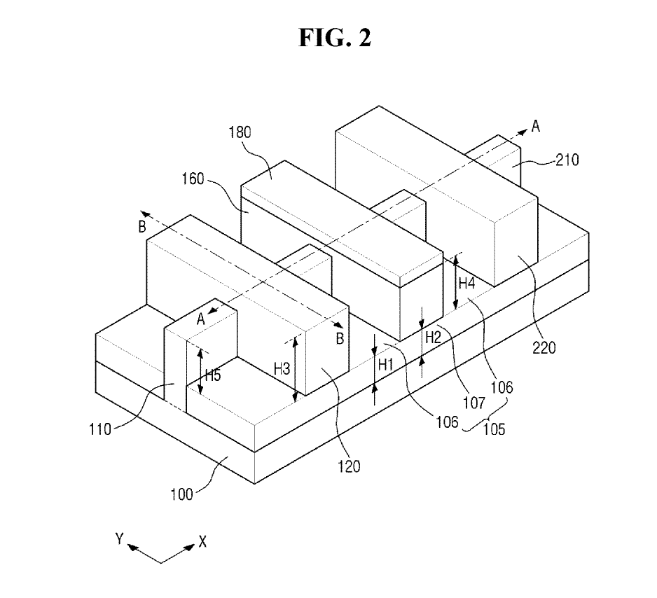

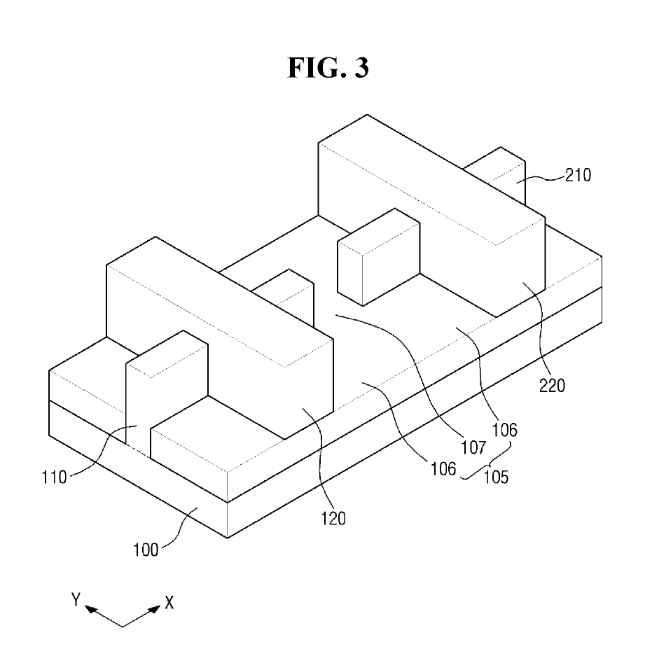

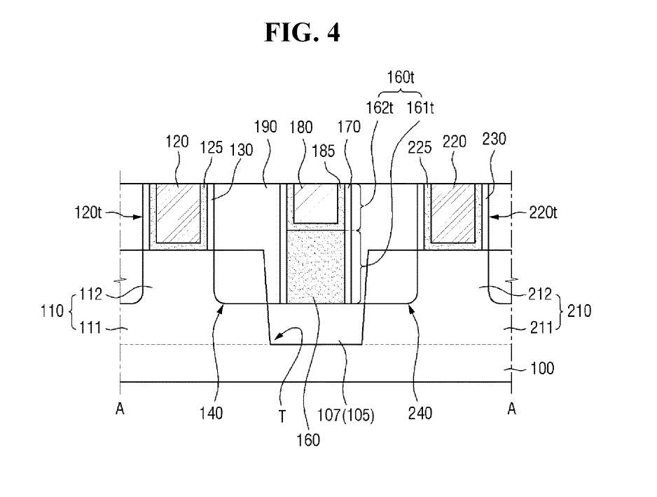

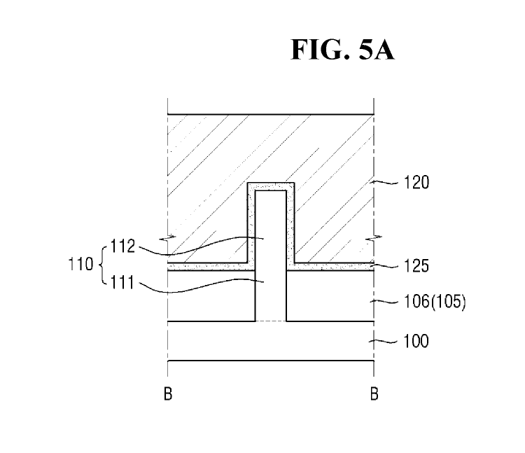

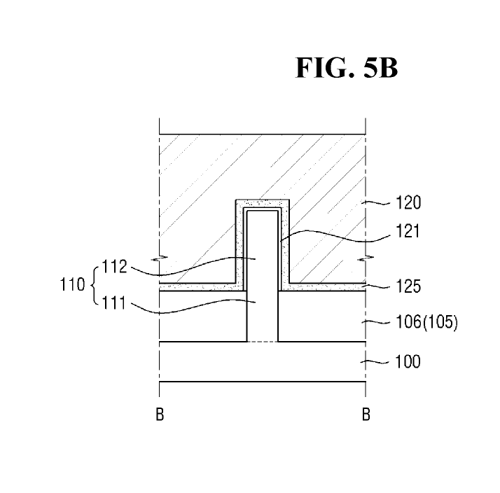

FIGS. 1 and 2 are a layout diagram and a perspective view, respectively, provided to explain a semiconductor device according to the first example embodiment. FIG. 3 is a partial perspective view provided to explain a fin-type pattern and a field insulating film of FIG. 2. FIG. 4 is a cross sectional view taken on line A-A of FIG. 2. FIGS. 5A and 5B are cross sectional views taken on line B-B of FIG. 2.

For reference, the fin-type pattern illustrated in FIGS. 1 to 3 includes a source/drain formed on the fin-type pattern.

Further, although the fin-type pattern configuration is illustrated in the drawings as an example, a body in a wire pattern configuration may be implemented instead of the fin-type pattern configuration.

Referring to FIGS. 1 to 5B, a semiconductor device 1 according to the first example embodiment may include a first fin-type pattern 110, a second fin-type pattern 210, a first gate electrode 120, a second gate electrode 220, an insulating line pattern 160 and a conductive pattern 180.

The substrate 100 may be a bulk silicon or a silicon-on-insulator (SOI), for example. Alternatively, the substrate 100 may be a silicon substrate, or may include other substances such as, for example, silicon germanium, indium antimonide, lead telluride compound, indium arsenide, indium phosphide, gallium arsenide, or gallium antimonide. Alternatively, the substrate 100 may be a base substrate having an epitaxial layer formed thereon.

The first fin-type pattern 110 and the second fin-type pattern 210 may be elongated in a first direction X, respectively. The first fin-type pattern 110 and the second fin-type pattern 210 may be formed abreast in a lengthwise direction.

The first fin-type pattern 110 and the second fin-type pattern 210, which are elongated in the first direction X, respectively, may thus include long sides 110a, 210a formed in the first direction X, respectively, and short sides 110b, 210b formed in a second direction Y.

For instance, when the first fin-type pattern 110 and the second fin-type pattern 210 are formed abreast in the lengthwise direction, it means that the short side 110b of the first fin-type active pattern 110 is opposed to, or facing, the short side 210b of the second fin-type pattern 210.

A person skilled in the art will be able to distinguish the long sides 110a, 210a and the short sides 110b, 210b even when the first and the second fin-type patterns 110, 210 have rounded corners.

The first fin-type pattern 110 and the second fin-type pattern 210 may be formed adjacent to each other. The first fin-type pattern 110 and the second fin-type pattern 210 formed abreast in the lengthwise direction may be isolated by an isolating trench T.

The isolating trench T may be formed between the first fin-type pattern 110 and the second fin-type pattern 210. More specifically, the isolating trench T may be formed in contact with the short side 110b of the first fin-type pattern 110 and the short side 210b of the second fin-type pattern 210.

The first fin-type pattern 110 and the second fin-type pattern 210 refer to active patterns for use in the multigate transistor. Accordingly, the first fin-type pattern 110 and the second fin-type pattern 210 may be formed as the channels are connected with each other along three surfaces of the fin, or alternatively, the channels may be formed on two opposed surfaces of the fin.

The first fin-type pattern 110 and the second fin-type pattern 210 may be part of the substrate 100, and may include an epitaxial layer grown on the substrate 100.

The first fin-type pattern 110 and the second fin-type pattern 210 may include an element semiconductor material such as silicon or germanium. Further, the first fin-type pattern 110 and the second fin-type pattern 210 may include a compound semiconductor such as a Iv-Iv group compound semiconductor or a III-V group compound semiconductor.

Specifically, take the Iv-Iv group compound semiconductor as an example, the first fin-type pattern 110 and the second fin-type pattern 210 may be a binary compound comprising at least two of carbon (C), silicon (Si), germanium (Ge) and tin (Sn), a ternary compound comprising at least three of carbon (C), silicon (Si), germanium (Ge) and tin (Sn), or the compounds comprising at least two of carbon (C), silicon (Si), germanium (Ge) and tin (Sn) doped with IV group element.

Take the III-V group compound semiconductor for instance, the first fin-type pattern 110 and the second fin-type pattern 210 may be one of a binary compound, a ternary compound or a quaternary compound which is formed by a combination of a III group element with a V group element. The III group element may be at least one of aluminum (Al), gallium (Ga), and indium (In). The V group element may be one of phosphorus (P), arsenic (As) and antimony (Sb).

In the semiconductor device according to example embodiments, it is assumed that the first fin-type pattern 110 and the second fin-type pattern 210 are silicon fin-type patterns which include silicon.

A field insulating film 105 may be formed on the substrate 100. The field insulating film 105 may be formed around the first fin-type pattern 110 and the second fin-type pattern 210. As such, the first fin-type pattern 110 and the second fin-type pattern 210 may be defined by the field insulating film 105.

The field insulating film 105 may include a first region 106 and a second region 107. The first region 106 of the field insulating film 105 may contact the long side 110a of the first fin-type pattern 110 and the long side 210a of the second fin-type pattern 210. The first region 106 of the field insulating film 105 may be elongated in the first direction X, along the long side 110a of the first fin-type pattern 110 and the long side 210a of the second fin-type pattern 210.

The second region 107 of the field insulating film 105 may contact the short side 110b of the first fin-type pattern 110 and the short side 210b of the second fin-type pattern 210. The second region 107 of the field insulating film 105 may be formed between the short side 110b of the first fin-type pattern 110 and the short side 210b of the second fin-type pattern 210.

The second region 107 of the field insulating film 105 may partially fill the isolating trench T formed between the first fin-type pattern 110 and the second fin-type pattern 210.

The upper surface of the field insulating film 105 may be lower than the upper surface of the first fin-type pattern 110 and the upper surface of the second fin-type pattern 210. More specifically, the upper surface of the first region 106 of the field insulating film 105 and the upper surface of the second region 107 of the field insulating film 105 are lower than the upper surface of the first fin-type pattern 110 and the upper surface of the second fin-type pattern 210, respectively.

With reference to the bottom of the isolating trench T, the height H1 of the first region 106 of the field insulating film 105 and the height H2 of the second region 107 of the field insulating film 105 may be lower than the height of the first fin-type pattern 110 and the height of the second fin-type pattern 210, respectively.

The field insulating film 105 may partially surround the first fin-type pattern 110 and the second fin-type pattern 210. The first fin-type pattern 110 may include a lower portion 111 and an upper portion 112, and the second fin-type pattern 210 may include a lower portion 211 and an upper portion 212.

The field insulating film 105 may surround the lower portion 111 of the first fin-type pattern and the lower portion 211 of the second fin-type pattern. However, the field insulating film 105 does not surround the upper portion 112 of the first fin-type pattern and the upper portion 212 of the second fin-type pattern. The field insulating film 105 may not contact the upper portion 112 of the first fin-type pattern and the upper portion 212 of the second fin-type pattern.

The upper portion 112 of the first fin-type pattern and the upper portion 212 of the second fin-type pattern may protrude upward and higher than the upper surface of the first region 106 of the field insulating film 105 and the upper surface of the second region 107 of the field insulating film 105, respectively.

The field insulating film 105 may include, for example, an oxide layer, a nitride layer, an oxynitride layer, or a layer combining the above.

An interlayer insulating film 190 may be formed on the field insulating film 105. The interlayer insulating film 190 may cover the first fin-type pattern 110, the second fin-type pattern 210 and the field insulating film 105.

The interlayer insulating film 190 may include a first trench 120t, a second trench 220t, and a third trench 160t.

The first trench 120t may extend in the second direction Y and intersect the first fin-type pattern 110. The first trench 120t may partially expose the first fin-type pattern 110. The second trench 220t may extend in the second direction Y and intersect the second fin-type pattern 210. The second trench 220t may partially expose the second fin-type pattern 210.

The third trench 160t may extend in the second direction Y, between the first trench 120t and the second trench 220t. The third trench 160t may be formed so as to span between the first fin-type pattern 110 and the second fin-type pattern 210. The third trench 160t may expose the upper surface of the second region 107 of the field insulating film 105.

The third trench 160t may include an upper portion 162t and a lower portion 161t. The manner in which the upper portion 162t of the third trench and the lower portion 161t of the third trench are distinguished from each other will be explained below, when explaining the insulating line pattern 160 and the conductive pattern 180.

In the semiconductor device according to the first example embodiment, the upper portion 162t of the third trench and the lower portion 161t of the third trench may have substantially the same width as each other at an area near a boundary between the upper portion 162t of the third trench and the lower portion 161t of the third trench. In certain embodiments, the sidewall of the upper portion 162t of the third trench and the sidewall of the lower portion 161t of the third trench may be in the same plane.

The interlayer insulating film 190 may include at least one of silicon oxide, silicon nitride, silicon oxynitride, and a low-k dielectric material. For example, the low-k dielectric material may include flowable oxide (FOX), Tonen silazen (TOSZ), undoped silica glass (USG), borosilica glass (BSG), phosphosilica glass (PSG), borophosphosilica glass (BPSG), plasma-enhanced tetra ethyl ortho silicate (PETEOS), fluoride silicate glass (FSG), carbon-doped silicon oxide (CDO), xerogel, aerogel, amorphous-fluorinated carbon, organo silicate glass (OSG), parylene, bis-benzocyclobutenes (BCB), SiLK, polyimide, porous polymeric material, or a combination thereof, but is not limited thereto.

The first gate electrode 120 may be formed so as to extend in the second direction Y and intersect the first fin-type pattern 110. The first gate electrode 120 may be formed in the first trench 120t.

The first gate electrode 120 may be formed on the first fin-type pattern 110 and the field insulating film 105. The first gate electrode 120 may surround the first fin-type pattern 110 which protrudes upward and higher than the upper surface of the field insulating film 105, i.e., may surround the upper portion 112 of the first fin-type pattern.

The second gate electrode 220 may be formed so as to extend in the second direction Y and intersect the second fin-type pattern 210. The second gate electrode 220 may be formed in the second trench 220t.

The second gate electrode 220 may be formed on the second fin-type pattern 210 and the field insulating film 105. The second gate electrode 220 may surround the second fin-type pattern 210 which protrudes upward and higher than the upper surface of the field insulating film 105, i.e., may surround the upper portion 212 of the second fin-type pattern.

The first gate electrode 120 and the second gate electrode 220 may each include at least one of, for example, polycrystalline silicon (poly Si), amorphous silicon (a-Si), titanium (Ti), titanium nitride (TiN), tungsten nitride (WN), titanium aluminum (TiAl), titanium aluminum nitride (TiAlN), tantalum nitride (TaN), titanium carbide (TiC), tantalum carbide (TaC), tantalum carbonitride (TaCN), tantalum silicon nitride (TaSiN), tantalum (Ta), cobalt (Co), ruthenium (Ru), aluminum (Al) and tungsten (W).

For example, the first gate electrode 120 and the second gate electrode 220 may be formed by a replacement process (or gate last process), but are not limited thereto.

The insulating line pattern 160 may be formed on the second region 107 of the field insulating film 105. The insulating line pattern 160 may extend in the second direction Y.

The insulating line pattern 160 may be formed by partially filling the third trench 160t in which is exposed the upper surface of the second region 107 of the field insulating film 105. More specifically, the insulating line pattern 160 may be formed by filling the lower portion 161t of the third trench.

The insulating line pattern 160 may span between the first fin-type pattern 110 and the second fin-type pattern 210. The insulating line pattern 160 may be formed between the first fin-type pattern 110 and the second fin-type pattern 210. More specifically, the insulating line pattern 160 may span between the short side 110b of the first fin-type pattern 110 and the short side 210b of the second fin-type pattern 210.

The insulating line pattern 160 may be formed so as to span between the first fin-type pattern 110 and the second fin-type pattern 210, in which case the insulating line pattern 160 may not contact the first fin-type pattern 110 and the second fin-type pattern 210.

The sidewall of the third trench 160t with the insulating line pattern 160 formed therein may be defined by the interlayer insulating film 190, rather than defined by the first fin-type pattern 110 and the second fin-type pattern 210.

The upper surface of the insulating line pattern 160 may be lower than the upper surface of the first gate electrode 120 and the upper surface of the second gate electrode 220. Further, the upper surface of the insulating line pattern 160 may be higher than the upper surface of the first fin-type pattern 110 and the upper surface of the second fin-type pattern 210.

The height from the substrate 100 to the upper surface of the insulating line pattern 160 may be H2+H4, and the height from the substrate 100 to the upper surface of the first fin-type pattern 110 may be H2+H5. At this time, the height (H2+H4) from the substrate 100 to the upper surface of the insulating line pattern 160 may be greater than the height (H2+H5) from the substrate 100 to the upper surface of the first fin-type pattern 110.

The height H4 of the insulating line pattern 160 may be greater than the height H5 of the upper portion 112 of the first fin-type pattern protruding upward and higher than the upper surface of the second region 107 of the field insulating film 105, and may be greater than the height H5 of the upper portion 212 of the second fin-type pattern.

The bottom surface of the insulating line pattern 160 may be lower than the upper surface of the first fin-type pattern 110 and the upper surface of the second fin-type pattern 210. For example, the bottom surface of the insulating line pattern 160 may be closer to the bottom of the isolating trench T than are the upper surface of the first fin-type pattern 110 and the upper surface of the second fin-type pattern 210.

In the semiconductor device 1 according to the first example embodiment, the insulating line pattern 160 may contact the second region 107 of the field insulating film 105. The bottom surface of the insulating line pattern 160 may be in contact with the upper surface of the second region 107 of the field insulating film 105.

The insulating line pattern 160 may include an insulation material. The insulating line pattern 160 may not include a conductive material.

For example, the insulating line pattern 160 may include silicon oxide, silicon nitride, silicon oxynitride, flowable oxide (FOX), Tonen silazen (TOSZ), undoped silica glass (USG), borosilica glass (BSG), phosphosilica glass (PSG), borophosphosilica glass (BPSG), plasma-enhanced tetra ethyl ortho silicate (PETEOS), fluoride silicate glass (FSG), carbon-doped silicon oxide (CDO), xerogel, aerogel, amorphous-fluorinated carbon, organo silicate glass (OSG), parylene, bis-benzocyclobutenes (BCB), SiLK, polyimide, porous polymeric material, or a combination thereof, but is not limited thereto.

A conductive pattern 180 may be formed on the insulating line pattern 160. The conductive pattern 180 may extend in the second direction Y.

The conductive pattern 180 may be formed by partially filling the third trench 160t. More specifically, the conductive pattern 180 may be formed by filling the upper portion 162t of the third trench.

The conductive pattern 180 may span between the first fin-type pattern 110 and the second fin-type pattern 210. The conductive pattern 180 may be formed between the first fin-type pattern 110 and the second fin-type pattern 210.

The upper surface of the insulating line pattern 160 may be higher than the upper surface of the first fin-type pattern 110 and the upper surface of the second fin-type pattern 210, in which case the conductive pattern 180 on the insulating line pattern 160 may not contact the first fin-type pattern 110 and the second fin-type pattern 210.

The upper surface of the conductive pattern 180 may be in the same plane as the upper surface of the first gate electrode 120 and the upper surface of the second gate electrode 220. The upper surface of the conductive pattern 180 may be in the same plane as the upper surface of the interlayer insulating film 190.

The conductive pattern 180 may be formed on the insulating line pattern 160, in which case the bottom surface of the conductive pattern 180 may be higher than the upper surface of the first fin-type pattern 110 and the upper surface of the second fin-type pattern 210.

The first gate electrode 120 and the second gate electrode 220 formed on the field insulating film 105 may have a height H3, and the height of the conductive pattern 180 formed on the insulating line pattern 160 may be (H1+H3)−(H2+H4) (i.e., the sum of heights H1 and H3 minus the sum of heights H2 and H4). While there may be some variations depending on the relationship between the height H1 of the first region 106 of the field insulating film 105 and the height H2 of the second region 107 of the field insulating film 105, the height H3 of the first gate electrode 120 and the height H3 of the second gate electrode 220 may be greater than the height of the conductive pattern 180.

The conductive pattern 180 may include at least one of, for example, polycrystalline silicon (poly Si), amorphous silicon (a-Si), titanium (Ti), titanium nitride (TiN), tungsten nitride (WN), titanium aluminum (TiAl), titanium aluminum nitride (TiAlN), tantalum nitride (TaN), titanium carbide (TiC), tantalum carbide (TaC), tantalum carbonitride (TaCN), tantalum silicon nitride (TaSiN), tantalum (Ta), cobalt (Co), ruthenium (Ru), aluminum (Al) and tungsten (W).

A first gate insulating film 125 may be formed between the first fin-type pattern 110 and the first gate electrode 120. The first gate insulating film 125 may be formed along the profile of the first fin-type pattern 110 protruding upward and higher than the field insulating film 105.

Further, the first gate insulating film 125 may be disposed between the first gate electrode 120 and the field insulating film 105. The first gate insulating film 125 may be formed along the sidewall and the bottom surface of the first trench 120t.

A second gate insulating film 225 may be formed between the second fin-type pattern 210 and the second gate electrode 220. The second gate insulating film 225 may be formed along the profile of the second fin-type pattern 210 protruding upward and higher than the field insulating film 105.

The second gate insulating film 225 may be disposed between the second gate electrode 220 and the field insulating film 105. The second gate insulating film 225 may be formed along the sidewall and the bottom surface of the second trench 220t.

Further, as illustrated in FIG. 5B, an interfacial layer 121 may be additionally formed between the first gate insulating film 125 and the first fin-type pattern 110. The interfacial layer may be additionally formed between the second gate insulating film 225 and the second fin-type pattern 210.

Although not illustrated in FIG. 4, the interfacial layer may also be additionally formed between the first gate insulating film 125 and the first fin-type pattern 110 and between the second gate insulating film 225 and the second fin-type pattern 210.

As illustrated in FIG. 5B, the interfacial layer 121 may be formed along the profile of the first fin-type pattern 110 which protrudes higher than the upper surface of the first field insulating film 105, although example embodiments are not limited thereto.

The interfacial layer 121 may extend along the upper surface of the field insulating film 105 according to a method used for forming the interfacial layer 121.

Each of the first gate insulating film 125 and the second gate insulating film 225 may include, but is not limited to, for example, silicon oxide, silicon oxynitride, silicon nitride and a high-k dielectric material with a higher dielectric constant than silicon oxide. For example, the high-k dielectric material may include one or more of hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

A conductive pattern liner 185 may be formed between the conductive pattern 180 and the insulating line pattern 160, and between the conductive pattern 180 and the interlayer insulating film 190. The conductive pattern liner 185 may be formed along the sidewall and the bottom surface of the conductive pattern 180. The conductive pattern 180 may be formed on the conductive pattern liner 185.

The conductive pattern liner 185 may be formed along the upper surface of the insulating line pattern 160 and along the sidewall of the upper portion 162t of the third trench. The conductive pattern liner 185 may contact the insulating line pattern 160.

For example, the conductive pattern liner 185 may include, but is not limited to, one or more of hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

A first spacer 130 may be formed on a sidewall of the first gate electrode 120 extending in the second direction Y. The first spacer 130 may be formed on a sidewall of the first trench 120t.

The first gate insulating film 125 may extend between the first spacer 130 and the sidewall of the first gate electrode 120.

A second spacer 230 may be formed on a sidewall of the second gate electrode 220 extending in the second direction Y. The second spacer 230 may be formed on a sidewall of the second trench 220t.

The second gate insulating film 225 may extend between the second spacer 230 and the sidewall of the second gate electrode 220.

A first liner 170 may be formed on the sidewall of the insulating line pattern 160 which extends in the second direction Y. Further, the first liner 170 may be formed on the sidewall of the conductive pattern 180.

The first liner 170 may be formed on the sidewall of the third trench 160t. The first liner 170 may extend on the sidewall of the lower portion 161t of the third trench and on the sidewall of the upper portion 162t of the third trench.

The first liner 170 may not be formed on the bottom surface of the third trench 160t. For instance, the first liner 170 may not be formed between the bottom surface of the insulating line pattern 160 and the upper surface of the second region 107 of the field insulating film 105.

The first liner 170 may not contact the first fin-type pattern 110 and the second fin-type pattern 210. The interlayer insulating film 190 may be interposed between the first liner 170 and the short side 110b of the first fin-type pattern 110, and between the first liner 170 and the short side 210b of the second fin-type pattern 210.

For instance, the first liner 170 may be disposed between the insulating line pattern 160 and the interlayer insulating film 190.

The first liner 170 may contact the upper surface of the second region 107 of the field insulating film 105. The height of the first liner 170 may be substantially the same as the thickness of the interlayer insulating film 190 which covers the second region 107 of the field insulating film 105.

The conductive pattern liner 185 formed on the sidewall of the conductive pattern 180 may extend between the first liner 170 and the conductive pattern 180.

The first liner 170 may include a material of a different etch selectivity from the insulating line pattern 160.

Each of the first spacer 130, the second spacer 230 and the first liner 170 may include at least one of, for example, silicon nitride (SiN), silicon oxynitride (SiON), silicon oxide (SiO2), silicon oxycarbonitride (SiOCN), and a combination thereof.

A first source/drain 140 may be formed on both sides of the first gate electrode 120. The first source/drain 140 may be formed between the first gate electrode 120 and the insulating line pattern 160.

The first source/drain 140 may be formed by doping an impurity in the upper portion 112 of the first fin-type pattern.

A second source/drain 240 may be formed on both sides of the second gate electrode 220. The second source/drain 240 may be formed between the second gate electrode 220 and the insulating line pattern 160.

The second source/drain 240 may be formed by doping an impurity in the upper portion 212 of the second fin-type pattern.

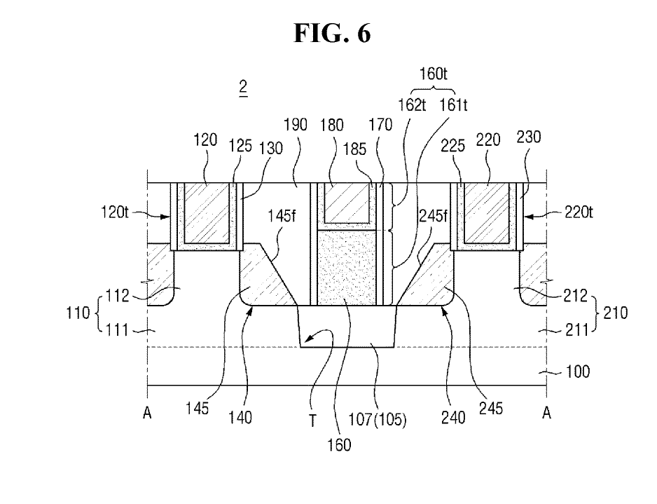

FIG. 6 is a view provided to explain a semiconductor device according to a second example embodiment. For convenience of explanation, differences that are not explained above with reference to FIGS. 1 to 5B will be more fully explained below.

Referring to FIG. 6, in the semiconductor device 2 according to the second example embodiment, the first source/drain 140 may include a first epitaxial layer 145 formed on the first fin-type pattern 110, and the second source/drain 240 may include a second epitaxial layer 245 formed on the second fin-type pattern 210.

The first epitaxial layer 145 may be formed so as to fill a recess formed on the upper portion 112 of the first fin-type pattern. The second epitaxial layer 245 may be formed so as to fill a recess formed on the upper portion 212 of the second fin-type pattern.

Referring to FIG. 6, each of the first epitaxial layer 145 formed on an end of the first fin-type pattern 110 and the second epitaxial layer 245 formed on an end of the second fin-type pattern 210 may include a facet 145f, 245f, but example embodiments are not limited thereto.

When the semiconductor device 2 according to the second example embodiment is a p-type metal oxide semiconductor (PMOS) transistor, the first epitaxial layer 145 and the second epitaxial layer 245 may include a compressive stress material. For example, the compressive stress material may be SiGe, which has a higher lattice constant compared to Si. For example, the compressive stress material can enhance mobility of the carrier in the channel region by exerting compressive stress on the first fin-type pattern 110 and the second fin-type pattern 210.

Alternatively, when the semiconductor device 2 is an NMOS transistor, the first epitaxial layer 145 and the second epitaxial layer 245 may include a tensile stress material. For example, when the first fin-type pattern 110 and the second fin-type pattern 210 are silicon (Si), the first epitaxial layer 145 and the second epitaxial layer 245 may be a material such as SiC, which has a smaller lattice constant than the silicon. For example, the tensile stress material can enhance mobility of the carrier in the channel region by exerting tensile stress on the first fin-type pattern 110 and the second fin-type pattern 210.

It is thus possible that when the first gate electrode 120 and the second gate electrode 220 are included in different types of MOS transistors, the first epitaxial layer 145 and the second epitaxial layer 245 may include different stress materials from each other.

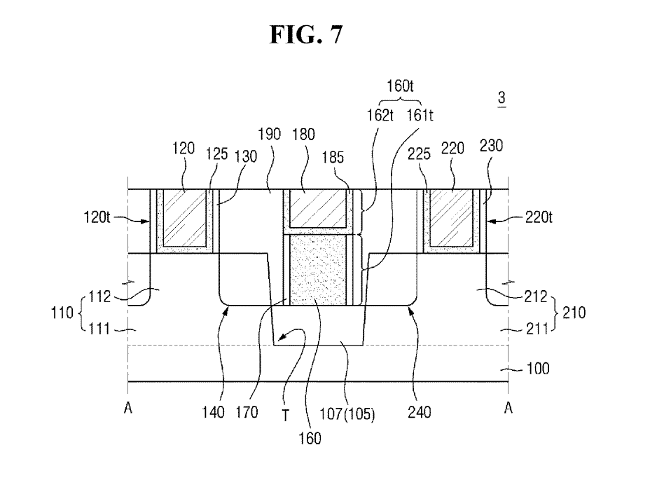

FIG. 7 is a view provided to explain a semiconductor device according to a third example embodiment. For convenience of explanation, differences that are not explained above with reference to FIGS. 1 to 5B will be explained more fully below.

Referring to FIG. 7, in the semiconductor device 3 according to the third example embodiment, the height of the first liner 170 may be less than the thickness of the interlayer insulating film 190 which covers the second region 107 of the field insulating film 105.

The first liner 170 may be formed on a sidewall of the lower portion 161t of the third trench. However, the first liner 170 may not be formed on the sidewall of the upper portion 162t of the third trench.

The first liner 170 may not extend to the upper surface of the interlayer insulating film 190. Accordingly, there may not be the first liner 170 interposed between the conductive pattern liner 185 formed on the sidewall of the conductive pattern 180 and the interlayer insulating film 190.

As illustrated in FIG. 7, the uppermost portion of the first liner 170 and the upper surface of the insulating line pattern 160 may be in the same plane, but this is provided only for convenience of explanation and the example embodiments are not limited thereto.

Accordingly, the uppermost portion of the first liner 170 may be higher or lower than the upper surface of the insulating line pattern 160. Accordingly, the conductive pattern liner 185 formed between the bottom surface of the conductive pattern 180 and the upper surface of the insulating line pattern 160 may be formed along the profile of the first liner 170 and the insulating line pattern 160.

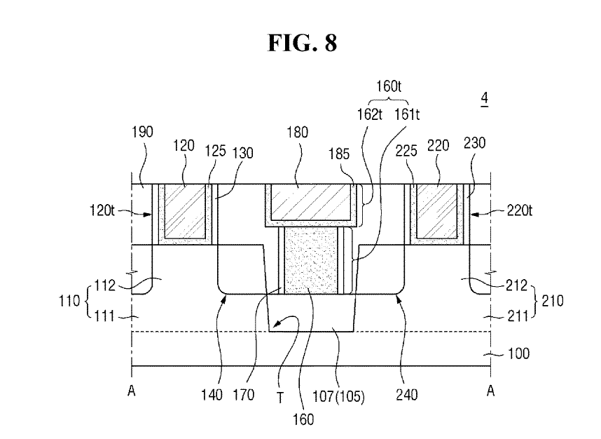

FIG. 8 is a view provided to explain a semiconductor device according to a fourth example embodiment. For convenience of explanation, differences that are not explained above with reference to FIGS. 1 to 5B will be explained more fully below.

Referring to FIG. 8, in a semiconductor device 4 according to the fourth example embodiment, the width of the upper portion 162t of the third trench may be greater than the width of the lower portion 161t of the third trench.

The width of the conductive pattern liner 185 formed on the bottom surface of the conductive pattern 180 may be greater than the sum of the width of the insulating line pattern 160 and the width of the first liner 170.

In the semiconductor device according to the fourth example embodiment, the width of the first gate electrode 120 and the width of the second gate electrode 220 may be less than the width of the conductive pattern 180.

The first liner 170 may be formed on the sidewall of the lower portion 161t of the third trench, but may not be formed on the sidewall of the upper portion 162t of the third trench.

The first liner 170 may not extend to the upper surface of the interlayer insulating film 190, in which case the height of the first liner 170 may be less than the thickness of the interlayer insulating film 190 which covers the second region 107 of the field insulating film 105.

As illustrated in FIG. 8, the uppermost portion of the first liner 170 and the upper surface of the insulating line pattern 160 may be in the same plane, but this is provided only for convenience of explanation and the example embodiments are not limited thereto.

Accordingly, the conductive pattern liner 185 formed between the bottom surface of the conductive pattern 180 and the upper surface of the insulating line pattern 160 may be formed along the profile of the first liner 170, the insulating line pattern 160 and the interlayer insulating film 190.

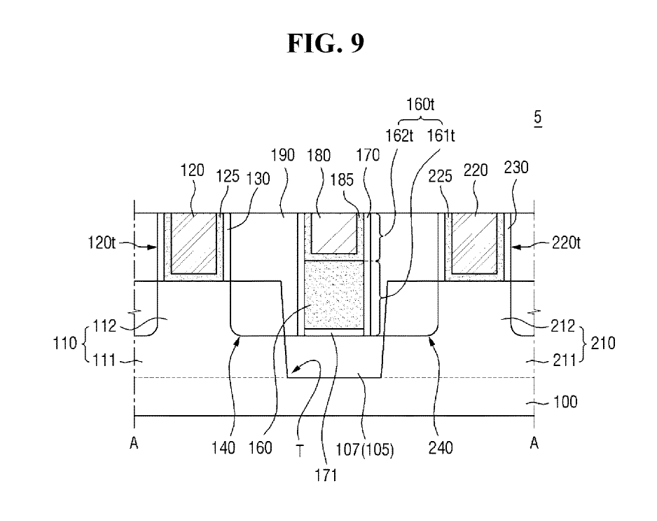

FIG. 9 is a view provided to explain a semiconductor device according to a fifth example embodiment. For convenience of explanation, differences that are not explained above with reference to FIGS. 1 to 5B will be explained more fully below.

Referring to FIG. 9, the semiconductor device 5 according to the fifth example embodiment may additionally include a second liner 171.

The second liner 171 may be formed along the bottom surface of the third trench 160t. However, the second liner 171 may not be formed along the sidewall of the third trench 160t. For instance, the second liner 171 may not be formed between the sidewall of the insulating line pattern 160 and the first liner 170, and between the sidewall of the conductive pattern 180 and the interlayer insulating film 190.

The second liner 171 may be formed between the bottom surface of the insulating line pattern 160 and the upper surface of the second region 107 of the field insulating film 105. The second liner 171 may contact the insulating line pattern 160.

While the second liner 171 may be formed between the insulating line pattern 160 and the second region 107 of the field insulating film 105, the bottom surface of the insulating line pattern 160 may still be lower than the upper surface of the first fin-type pattern 110 and the upper surface of the second fin-type pattern 210.

The second liner 171 may include, for example, silicon oxide, but may not be limited thereto.

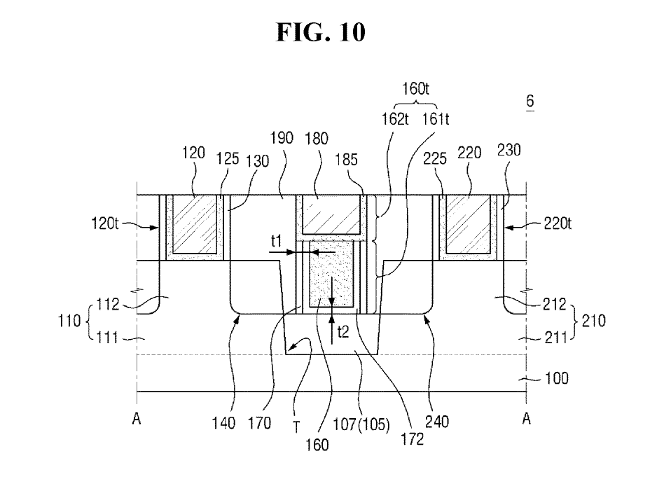

FIG. 10 is a view provided to explain a semiconductor device according to a sixth example embodiment.

Referring to FIG. 10, the semiconductor device 6 according to the sixth example embodiment may additionally include a third liner 172.

The third liner 172 may be formed along the sidewall and the bottom surface of the third trench 160t. More specifically, the third liner 172 may be formed along the sidewall and the bottom surface of the lower portion 161t of the third trench.

The third liner 172 may be formed along the sidewall and the bottom surface of the insulating line pattern 160. The third liner 172 may contact the second region 107 of the field insulating film 105.

The third liner 172 may not be formed on the sidewall of the conductive pattern 180. For instance, the third liner 172 may not be formed between the sidewall of the conductive pattern 180 and the interlayer insulating film 190.

The third liner 172 may include a first portion extending along the bottom surface of the third trench 160t, and a second portion extending along the sidewall of the third trench 160t.

The first portion of the third liner 172 may extend along the upper surface of the second region 107 of the field insulating film 105 between the insulating line pattern 160 and the second region 107 of the field insulating film 105. The first portion of the third liner 172 may be formed along the bottom surface of the insulating line pattern 160.

The second portion of the third liner 172 may extend along the sidewall of the insulating line pattern 160. The second portion of the third liner 172 may be formed on the first liner 170 that is formed on the sidewall of the third trench 160t.

The second portion of the second liner 171 may extend between the sidewall of the insulating line pattern 160 and the first liner 170. The second portion of the third liner 172 may be formed between the sidewall of the insulating line pattern 160 and the interlayer insulating film 190.

The first liner 170 and the third liner 172 may be formed along the sidewall and the bottom surface of the lower portion 162t of the third trench. The insulating line pattern 160 may be formed so as to fill the third trench 160t with the first liner 170 and the third liner 172 formed therein.

The first liner 170 and the third liner 172 may be formed on the sidewall of the insulating line pattern 160. However, the first liner 170 may not be formed on the bottom surface of the insulating line pattern 160 at a position where the third liner 172 may be formed.

Accordingly, the thickness t1 of the liners 170, 172 formed along the sidewall of the insulating line pattern 160 may be different from the thickness t2 of the liners 170, 172 formed along the bottom surface of the insulating line pattern 160.

In the semiconductor device 3 according to the sixth example embodiment, the thickness t1 of the liners 170, 172 formed along the sidewall of the insulating line pattern 160 may be greater than the thickness t2 of the liner 172 formed along the bottom surface of the insulating line pattern 160.

For example, the thickness t2 of the liner 172 formed along the upper surface of the second region 107 of the field insulating film 105 may be less than the thickness t1 of the liners 170, 172 protruding upward from the upper surface of the second region 107 of the field insulating film 105.

For example, the third liner 172 may include, but is not limited to, at least one of silicon nitride (SiN), silicon oxynitride (SiON), silicon oxide (SiO2), silicon oxycarbonitride (SiOCN), and a combination thereof.

The height of the first liner 170 may be less than the thickness of the interlayer insulating film 190 which covers the second region 107 of the field insulating film 105.

The first liner 170 may be formed on the sidewall of the lower portion 161t of the third trench. However, the first liner 170 may not be formed on the sidewall of the upper portion 162t of the third trench.

The first liner 170 may not extend to the upper surface of the interlayer insulating film 190. Accordingly, the first liner 170 and the third liner 172 may not be interposed between the interlayer insulating film 190 and the conductive pattern liner 185 formed on the sidewall of the conductive pattern 180.

As illustrated in FIG. 10, the uppermost portion of the first liner 170, the uppermost portion of the third liner 172, and the upper surface of the insulating line pattern 160 may be in the same plane, but this is provided only for convenience of explanation and the example embodiments are not limited thereto.

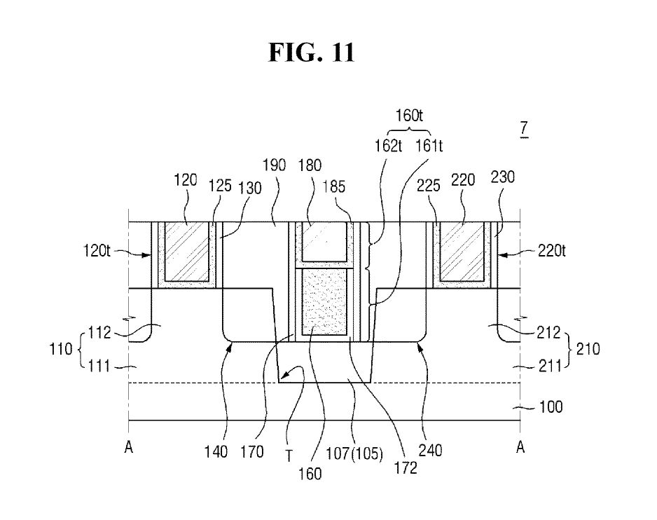

FIG. 11 is a view provided to explain a semiconductor device according to a seventh example embodiment. For convenience of explanation, differences that are not explained above with reference to FIG. 10 will be explained more fully below.

Referring to FIG. 11, in the semiconductor device 7 according to the seventh example embodiment, the height of the first liner 170 may be substantially the same as the thickness of the interlayer insulating film 190 which covers the second region 107 of the field insulating film 105.

The first liner 170 may extend on the sidewall of the lower portion 161t of the third trench and on the sidewall of the upper portion 162t of the third trench.

The first liner 170 and the third liner 172 may be interposed between the interlayer insulating film 190 and the sidewall of the insulating line pattern 160. Meanwhile, the first liner 170 may be interposed between the interlayer insulating film 190 and the conductive pattern 180, but the third liner 172 may not be interposed between the interlayer insulating film 190 and the conductive pattern 180.

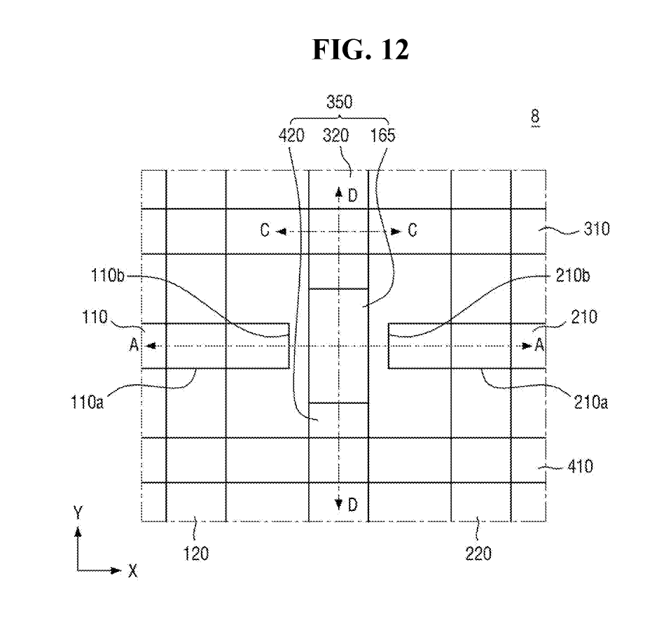

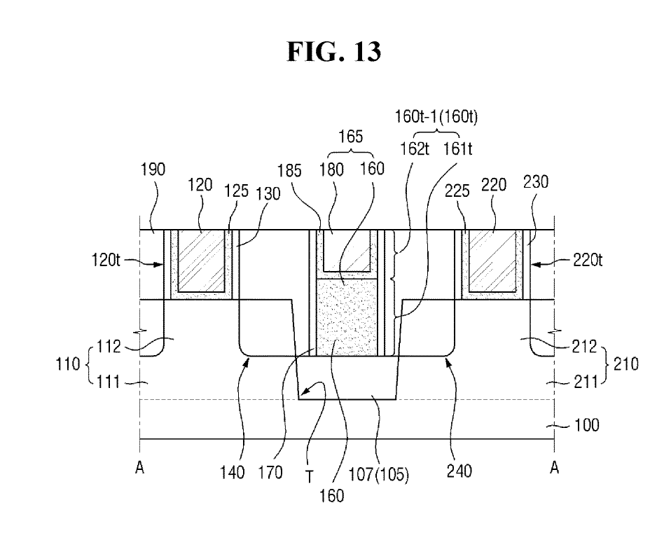

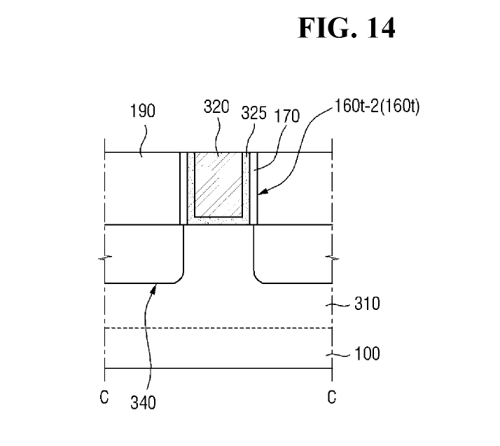

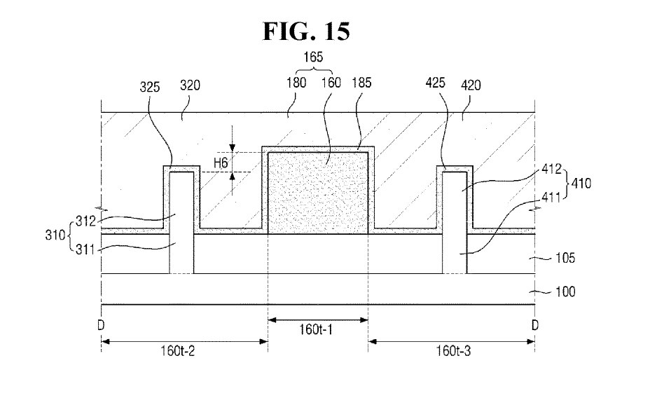

FIG. 12 is a layout diagram provided to explain a semiconductor device according to an eighth example embodiment. FIG. 13 is a cross sectional view taken on line A-A of FIG. 12. FIG. 14 is a cross sectional view taken on line C-C of FIG. 12. FIG. 15 is a cross sectional view taken on line D-D of FIG. 14.

For convenience of explanation, differences that are not explained above with reference to FIGS. 1 to 5B will be explained more fully below.

Further, the cross sectional view taken on line A-A of FIG. 12 may be illustrated in a similar manner as FIG. 4, but example embodiments are not limited thereto. Accordingly, the cross sectional view taken on line A-A of FIG. 12 may be illustrated in a similar manner as FIGS. 6 and 7 to 9.

Referring to FIGS. 12 to 15, the semiconductor device 8 according to the eighth example embodiment may include a first fin-type pattern 110, a second fin-type pattern 210, a third fin-type pattern 310, a fourth fin-type pattern 410, a first gate electrode 120, a second gate electrode 220, and a connect gate pattern 350.

The third fin-type pattern 310 may be elongated in a first direction X. The first fin-type pattern 110 and the third fin-type pattern 310 may be elongated in the first direction X, but the first fin-type pattern 110 and the third fin-type pattern 310 may be aligned in a second direction Y. Further, the second fin-type pattern 210 and the third fin-type pattern 310 may be aligned in the second direction Y.

In some embodiments, the long side of the first fin-type pattern 110 and the long side of the third fin-type pattern 310 may be opposed to each other, and the long side of the second fin-type pattern 210 and the long side of the third fin-type pattern 310 may be opposed to each other.

The fourth fin-type pattern 410 may be elongated in the first direction X. The fourth fin-type pattern 410 and the third fin-type pattern 310 may be formed abreast. The fourth fin-type pattern 410 may be aligned in the second direction Y.

The first fin-type pattern 110 and the second fin-type pattern 210 may be disposed between the third fin-type pattern 310 and the fourth fin-type pattern 410. The first fin-type pattern 110 and the second fin-type pattern 210 may be aligned longitudinally in the first direction X, between the third fin-type pattern 310 and the fourth fin-type pattern 410.

In some embodiments, the long side of the first fin-type pattern 110 and the long side of the fourth fin-type pattern 410 may be opposed to each other, and the long side of the second fin-type pattern 210 and the long side of the fourth fin-type pattern 310 may be opposed to each other.

The field insulating film 105 may be formed around the third fin-type pattern 310 and the fourth fin-type pattern 410. The field insulating film 105 may partially surround the third fin-type pattern 310 and the fourth fin-type pattern 410. The third fin-type pattern 310 and the fourth fin-type pattern 410 may be defined by the field insulating film 105.

The upper surface of the field insulating film 105 in contact with the long side of the third fin-type pattern 310 and the long side of the fourth fin-type pattern 410 may be lower than the upper surface of the third fin-type pattern 310 and the upper surface of the fourth fin-type pattern 410.

Description about the third fin-type pattern 310 and the fourth fin-type pattern 410 will not be redundantly provided below, but may be referred to the substantially the same description provided above about the first fin-type pattern 110 and the second fin-type pattern 210, respectively.

The connect gate pattern 350 may be elongated in the second direction Y. The connect gate pattern 350 may be formed in the third trench 160t.

The connect gate pattern 350 may be formed on the third fin-type pattern 310, the fourth fin-type pattern 410, and the field insulating film 105. However, the connect gate pattern 350 may not be formed on the first fin-type pattern 110 and the second fin-type pattern 210.

The connect gate pattern 350 may be formed so as to intersect the third fin-type pattern 310 and the fourth fin-type pattern 410. However, the connect gate pattern 350 may not intersect the first fin-type pattern 110 and the second fin-type pattern 210.

The connect gate pattern 350 may be formed so as to span between the first fin-type pattern 110 and the second fin-type pattern 210. For instance, the connect gate pattern 350 may span between the short side 110b of the first fin-type pattern 110 and the short side 210b of the second fin-type pattern 210.

Accordingly, the third fin-type pattern 310 and the fourth fin-type pattern 410 may be neighboring fin-type patterns which are intersected by the connect gate pattern 350. For instance, with reference to the connect gate pattern 350, there may not be any fin-type pattern protruding upward and higher than the upper surface of the field insulating film 105 between the third fin-type pattern 310 and the fourth fin-type pattern 410.

The connect gate pattern 350 may include the third gate electrode 320, the fourth gate electrode 420 and a connect pattern 165. The connect pattern 165 may be disposed between the third gate electrode 320 and the fourth gate electrode 420.

The connect pattern 165 may connect the third gate electrode 320 and the fourth gate electrode 420. The connect pattern 165 may include an insulating line pattern 160 formed on the field insulating film 105 between the first fin-type pattern 110 and the second fin-type pattern 210, and a conductive pattern 180 on the insulating line pattern 160. More specifically, the conductive pattern 180 may connect the third gate electrode 320 and the fourth gate electrode 420.

The third gate electrode 320 may intersect the third fin-type pattern 310. The fourth gate electrode 420 may intersect the fourth third fin-type pattern 410.

The third gate electrode 320 and the fourth gate electrode 420 may not pass through an area between the first fin-type pattern 110 and the second fin-type pattern 210. For instance, the third gate electrode 320 and the fourth gate electrode 420 may not pass through an area between the short side 110b of the first fin-type pattern 110 and the short side 210b of the second fin-type pattern 210.

The connect pattern 165 may not be formed on the third fin-type pattern 310 and the fourth fin-type pattern 410. The connect pattern 165 may not intersect the third fin-type pattern 310 and the fourth fin-type pattern 410, respectively.

The connect pattern 165 may not contact the first fin-type pattern 110 and the second fin-type pattern 210. For instance, the insulating line pattern 160 and the conductive pattern 180 may not contact the first fin-type pattern 110 and the second fin-type pattern 210, respectively.

Further, referring to FIGS. 4, 6, and 7 to 11, the width of the conductive pattern 180 in the first direction X may be equal to or greater than the width of the first gate electrode 120 and the width of the second gate electrode 220 in the first direction X.

Additionally, the width of the conductive pattern 180 in the first direction X may be equal to or greater than the width of the insulating line pattern 160 in the first direction X.

The insulating line pattern 160 may contact the upper surface of the field insulating film 105. The upper surface of the insulating line pattern 160 may be higher than the upper surface of the third fin-type pattern 310 and the upper surface of the fourth fin-type pattern 410.

For example, with reference to the substrate 100, the upper surface of the insulating line pattern 160 may be higher than the upper surface of the third fin-type pattern 310 and the upper surface of the fourth fin-type pattern 410 by H6.

The conductive pattern 180 may be formed on the insulating line pattern 160, in which case the bottom surface of the conductive pattern 180 may be higher than the upper surface of the third fin-type pattern 310 and the upper surface of the fourth fin-type pattern 410.

The conductive pattern liner 185 may be interposed between the insulating line pattern 160 and the conductive pattern 180, in which case the upper surface of the conductive pattern 180 may be higher than the upper surface of the third fin-type pattern 310 and the upper surface of the fourth fin-type pattern 410 by more than height H6.

The third gate electrode 320 may extend in the second direction Y so as to intersect the third fin-type pattern 310. The third gate electrode 320 may be formed on the third fin-type pattern 310 and the field insulating film 105.

The third gate electrode 320 may surround the third fin-type pattern 310 which protrudes upward and higher than the upper surface of the field insulating film 105, i.e., may surround the upper portion 312 of the third fin-type pattern.

The fourth gate electrode 420 may extend in the second direction Y so as to intersect the fourth fin-type pattern 410. The fourth gate electrode 420 may be formed on the fourth fin-type pattern 410 and the field insulating film 105.

The fourth gate electrode 420 may surround the fourth fin-type pattern 410 which protrudes upward and higher than the upper surface of the field insulating film 105, i.e., may surround the upper portion 412 of the fourth fin-type pattern.

The third gate electrode 320, the fourth gate electrode 420 and the conductive pattern 180 may be connected with each other. The third gate electrode 320, the fourth gate electrode 420 and the conductive pattern 180 may be electrically connected with each other.

The upper surface of the third gate electrode 320, the upper surface of the fourth gate electrode 420 and the upper surface of the conductive pattern 180 may be located in the same plane.

Additionally, the conductive pattern 180 may be formed on the insulating line pattern 160, in which case the height of the third gate electrode 320 and the height of the fourth gate electrode 420 may be greater than the height of the conductive pattern 180.

Each of the third gate electrode 320 and the fourth gate electrode 420 may include at least one of, for example, polycrystalline silicon (poly-Si), amorphous silicon (a-Si), titanium (Ti), titanium nitride (TiN), tungsten nitride (WN), titanium aluminum (TiAl), titanium aluminum nitride (TiAlN), tantalum nitride (TaN), titanium carbide (TiC), tantalum carbide (TaC), tantalum carbonitride (TaCN), tantalum silicon nitride (TaSiN), tantalum (Ta), cobalt (Co), ruthenium (Ru), aluminum (Al) and tungsten (W).

As illustrated in FIG. 12, the first gate electrode 120 and the second gate electrode 220 may intersect the third fin-type pattern 310, respectively, but example embodiments are not limited thereto.

As described above, the connect gate pattern 350, i.e., the third gate electrode 320, the fourth gate electrode 420 and the connect pattern 165, may be formed in the third trench 160t. As illustrated in FIGS. 13-16, the third trench 160t may include a first portion 160t-1, a second portion 160t-2 and a third portion 160t-3.

The first portion 160t-1 of the third trench may include a portion located between the short side of the first fin-type pattern 110 and the short side of the second fin-type pattern 210. The second portion 160t-2 of the third trench may intersect the third fin-type pattern 310, thus exposing the third fin-type pattern 310. The third portion 160t-3 of the third trench may intersect the fourth fin-type pattern 410, thus exposing the fourth fin-type pattern 410.

The connect pattern 165 may be formed by filling the first portion 160t-1 of the third trench, the third gate electrode 320 may be formed by filling the second portion 160t-2 of the third trench, and the fourth gate electrode 420 may be formed by filling the third portion 160t-3 of the third trench.

A third gate insulating film 325 may be formed between the third fin-type pattern 310 and the third gate electrode 320. The third gate insulating film 325 may be formed along the profile of the third fin-type pattern 310 protruding upward and higher than the field insulating film 105.

Further, the third gate insulating film 325 may be disposed between the third gate electrode 320 and the field insulating film 105. The third gate insulating film 325 may be formed along the sidewall and a bottom surface of the second portion 160t-2 of the third trench.

The third gate insulating film 325 may include a portion which extends along the sidewall of the insulating line pattern 160 opposite to the third gate electrode 320. For instance, a portion of the third gate insulating film 325 may be formed between the third gate electrode 320 and the insulating line pattern 160.

A portion of the third gate insulating film 325 may extend between the sidewall of the third gate electrode 320 and the sidewall of the insulating line pattern 160 which is opposed to the sidewall of the third gate electrode 320. The third gate insulating film 325 may be connected with the conductive pattern liner 185 formed on the upper surface of the insulating line pattern 160.

Further, the third gate insulating film 325 may not extend between the bottom surface of the insulating line pattern 160 and the upper surface of the field insulating film 105. Accordingly, the third gate insulating film 325 may define the second portion 160t-2 of the third trench where the third gate electrode 320 is formed.

The third gate insulating film 325 formed between the third gate electrode 320 and the insulating line pattern 160 may directly contact the sidewall of the insulating line pattern 160 which is opposite the third gate electrode 320.

The fourth gate insulating film 425 may be formed between the fourth fin-type pattern 410 and the fourth gate electrode 420. The fourth gate insulating film 425 may be formed along the profile of the fourth fin-type pattern 410 protruding upward and higher than the field insulating film 105.

Further, the fourth gate insulating film 425 may be disposed between the fourth gate electrode 420 and the field insulating film 105. The fourth gate insulating film 425 may be formed along the sidewall and the bottom surface of the third portion 160t-3 of the third trench.

The fourth gate insulating film 425 may include a portion which extends along the sidewall of the insulating line pattern 160 opposed to the fourth gate electrode 420. For instance, a portion of the fourth gate insulating film 425 may be formed between the fourth gate electrode 420 and the insulating line pattern 160.

A portion of the fourth gate insulating film 425 may extend between the sidewall of the fourth gate electrode 420 and the sidewall of the insulating line pattern 160 which is opposed to the sidewall of the fourth gate electrode 420. The fourth gate insulating film 425 may be connected with the conductive pattern liner 185 formed on the upper surface of the insulating line pattern 160.

Further, the fourth gate insulating film 425 may not extend between the bottom surface of the insulating line pattern 160 and the upper surface of the field insulating film 105. Accordingly, the fourth gate insulating film 425 may define the third portion 160t-2 of the third trench where the fourth gate electrode 420 is formed.

The fourth gate insulating film 425 formed between the fourth gate electrode 420 and the insulating line pattern 160 may directly contact the sidewall of the insulating line pattern 160 which is opposite to the fourth gate electrode 420.

Each of the third gate insulating film 325 and the fourth gate insulating film 425 may include, but is not limited to, for example, silicon oxide, silicon oxynitride, silicon nitride and a high-k dielectric material with a greater dielectric constant than silicon oxide. For example, the high-k dielectric material may include one or more of hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

As described above, the conductive pattern liner 185 formed on the upper surface of the insulating line pattern 160 may be connected with the third gate insulating film 325 and the fourth gate insulating film 425, respectively. Further, the conductive pattern liner 185, the third gate insulating film 325 and the fourth gate insulating film 425 each may include a high-k dielectric insulating film.

Further, the conductive pattern liner 185 may be formed when the third gate insulating film 325 and the fourth gate insulating film 425 are formed.

As such, the conductive pattern liner 185, the third gate insulating film 325 and the fourth gate insulating film 425 may be the high-k dielectric gate insulating films which are formed along the profile of the third fin-type pattern 310 that protrudes higher than the upper surface of the field insulating film 105, along the profile of the fourth fin-type pattern 410, and along the sidewall and the upper surface of the insulating line pattern 160.

The first liner 170 may extend on the sidewall of the third gate electrode 320 and on the sidewall of the fourth gate electrode 420.

For example, the third source/drain 340 may be formed on both sides of the third gate electrode 320. The third source/drain 340 may be formed by doping an impurity in the third fin-type pattern 310.

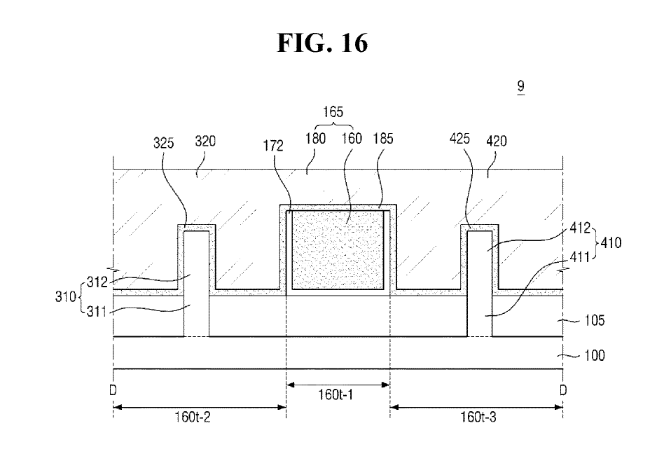

FIG. 16 is a view provided to explain a semiconductor device according to a ninth example embodiment. For convenience of explanation, differences that are not explained above with reference to FIGS. 12 to 15 will be mainly explained below.

For reference, FIG. 16 is a cross sectional view taken on line D-D of FIG. 12. Further, in the semiconductor device according to the sixth example embodiment, the cross sectional view taken on line A-A of FIG. 9 may be substantially identical to any of FIGS. 10 and 11.

Referring to FIG. 16, the semiconductor device 9 according to the ninth example embodiment may additionally include a third liner 172.

The third liner 172 may be formed along the sidewall and the bottom surface of the first portion 160t-1 of the third trench. The third liner 172 may be formed along the sidewall and the bottom surface of the insulating line pattern 160.

The third liner 172 may include a portion extending along the sidewall of the third gate electrode 320 opposed to the insulating line pattern 160. A portion of the third liner 172 may be formed between the third gate electrode 320 and the insulating line pattern 160.

A portion of the third liner 172 may be formed between the sidewall of the third gate electrode 320 and the sidewall of the insulating line pattern 160 which is opposed to the sidewall of the third gate electrode 320. A portion of the third liner 172 may be formed between the third gate insulating film 325 and the sidewall of the insulating line pattern 160 opposed to the third gate electrode 320.

Further, the third liner 172 may extend between the bottom surface of the insulating line pattern 160 and the upper surface of the field insulating film 105. However, the third liner 172 may not extend between the bottom surface of the third gate electrode 320 and the upper surface of the field insulating film 105.

The third liner 172 may include a portion extending along the sidewall of the fourth gate electrode 420 opposed to the insulating line pattern 160. A portion of the third liner 172 may be formed between the fourth gate electrode 420 and the insulating line pattern 160.

A portion of the third liner 172 may be formed between the sidewall of the fourth gate electrode 420 and the sidewall of the insulating line pattern 160 which is opposed to the sidewall of the fourth gate electrode 420. A portion of the third liner 172 may be formed between the fourth gate insulating film 425 and the sidewall of the insulating line pattern 160 opposed to the fourth gate electrode 420.

The third liner 172 may not extend between the bottom surface of the fourth gate electrode 420 and the upper surface of the field insulating film 105.

Accordingly, the third liner 172 may define the first portion 160t-1 of the third trench where the insulating line pattern 160 is formed.

The third gate insulating film 325 and the third liner 172 formed between the sidewall of the third gate electrode 320 and the sidewall of the insulating line pattern 160 which is opposed to the sidewall of the third gate electrode 320 may directly contact each other.

The fourth gate insulating film 325 and the third liner 172 formed between the sidewall of the fourth gate electrode 420 and the sidewall of the insulating line pattern 160 which is opposed to the sidewall of the fourth gate electrode 420 may directly contact each other.

The third liner 172 may not extend between the conductive pattern 180 and the third gate electrode 320, and may not extend between the conductive pattern 180 and the fourth gate electrode 420.

Hereinbelow, a method for fabricating a semiconductor device according to an example embodiment will be explained with reference to FIGS. 8 and 17 to 27.

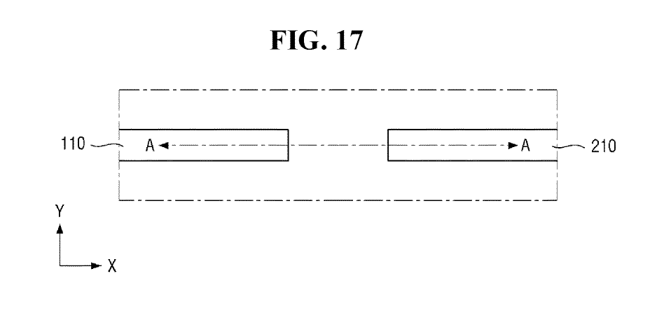

FIGS. 17 to 27 are views illustrating intermediate stages of fabrication, provided to explain a method for fabricating a semiconductor device according to an example embodiment.

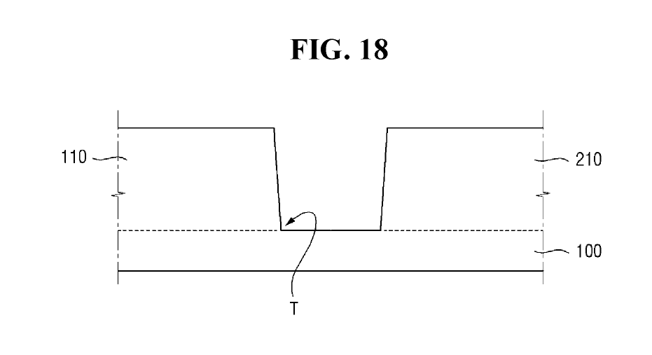

Referring to FIGS. 17 and 18, the first fin-type pattern 110 and the second fin-type pattern 210 elongated in the first direction X are formed on the substrate 100.

The first fin-type pattern 110 and the second fin-type pattern 210 may be longitudinally aligned in the first direction X.

The isolating trench T for isolating the first fin-type pattern 110 from the second fin-type pattern 210 may be formed between the first fin-type pattern 110 and the second fin-type pattern 210.

As illustrated, the upper surface of the first fin-type pattern 110 and the upper surface of the second fin-type pattern 210 may be exposed, but is not limited thereto. For example, in certain embodiments, the remainder of the mask pattern used in the process of forming the first fin-type pattern 110 and the second fin-type pattern 210 may stay on the upper surface of the first fin-type pattern 110 and the upper surface of the second fin-type pattern 210.

The following description is based on a cross sectional view taken on line A-A of FIG. 17.

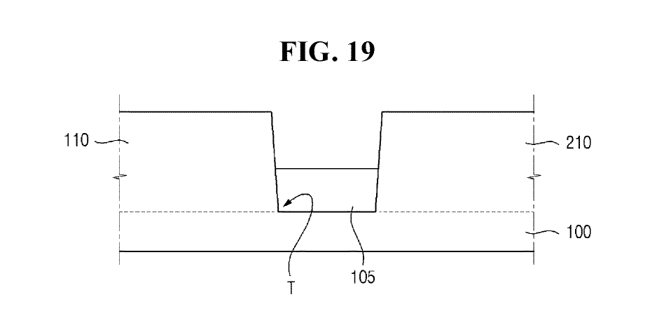

Referring to FIG. 19, the field insulating film 105 partially surrounding the first fin-type pattern 110 and the second fin-type pattern 210 may be formed.

The field insulating film 105 may partially fill the isolating trench T formed between the first fin-type pattern 110 and the second fin-type pattern 210.

In the process of forming the field insulating film 105 for partially surrounding the first fin-type pattern 110 and the second fin-type pattern 210, doping for the purpose of adjusting threshold voltage may be performed on the first fin-type pattern 110 and the second fin-type pattern 210, although example embodiments are not limited thereto.

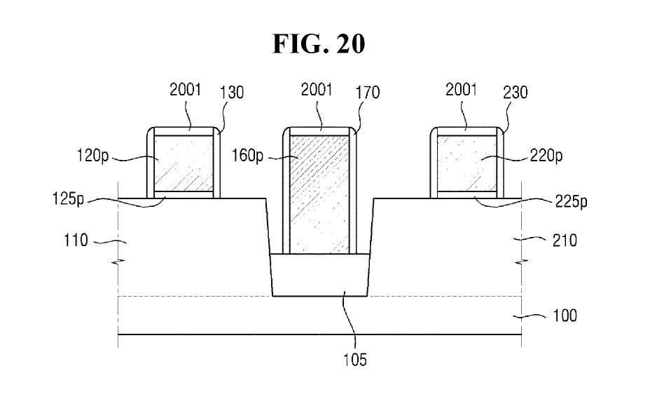

Referring to FIG. 20, using the first mask pattern 2001, an etching process may be performed, thus forming a first dummy gate electrode 120p, a second dummy gate electrode 220p and a third dummy gate electrode 160p.

The first dummy gate electrode 120p may extend in the second direction Y and may be formed on the first fin-type pattern 110. The first dummy gate insulating film 125p may be formed between the first dummy gate electrode 120p and the first fin-type pattern 110.

The second dummy gate electrode 220p may extend in the second direction Y and may be formed on the second fin-type pattern 210. The second dummy gate insulating film 225p may be formed between the second dummy gate electrode 220p and the second fin-type pattern 210.

The third dummy gate electrode 160p may extend in the second direction Y, and may be formed between the first fin-type pattern 110 and the second fin-type pattern 210. The third dummy gate electrode 160p may be formed on the field insulating film 105 which is formed between the short side of the first fin-type pattern 110 and the short side of the second fin-type pattern 210.

As illustrated, the third dummy gate insulating film may not be formed between the third dummy gate electrode 160p and the field insulating film 105, but this is provided only for convenience of explanation and example embodiments are not limited thereto.

Depending on a method used for forming the first dummy gate insulating film 125p and the second dummy gate insulating film 225p, the third dummy gate insulating film may be formed between the third dummy gate electrode 160p and the field insulating film 105.

Each of the first to the third dummy gate electrodes 120p, 220p, and 160p may include, but is not limited to, for example, polysilicon or amorphous silicon.

The first spacer 130 may then be formed on the sidewall of the first dummy gate electrode 120p. After the first spacer 130 is formed, the second spacer 230 may be formed on the sidewall of the second dummy gate electrode 220p, and the first liner 170 may be formed on the sidewall of the third dummy gate electrode 160p.

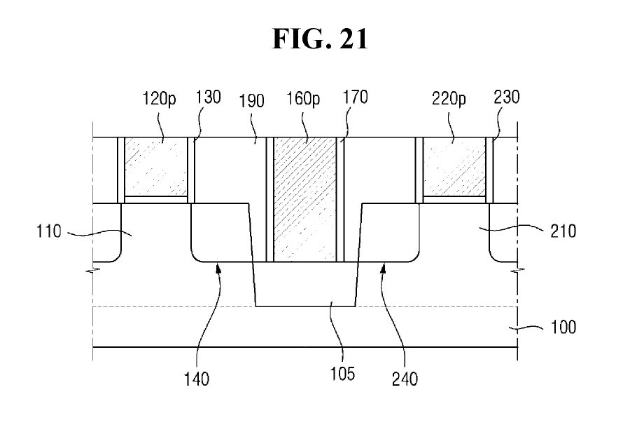

Referring to FIG. 21, the first source/drain 140 may be formed on both sides of the first dummy gate electrode 120p, within the first fin-type pattern 110.

The second source/drain 240 may be formed on both sides of the second dummy gate electrode 220p, within the second fin-type pattern 210.

As described above with reference to FIG. 6, each of the first source/drain 140 and the second source/drain 240 may include an epitaxial layer.

The interlayer insulating film 190 may then be formed on the field insulating film 105, covering the first fin-type pattern 110, the second fin-type pattern 210 and the first to the third dummy gate electrodes 120p, 220p, 160p.

The interlayer insulating film 190 may be planarized until the upper surfaces of the first to the third dummy gate electrodes 120p, 220p, and 160p are exposed. As a result, the first mask pattern 2001 may be removed.

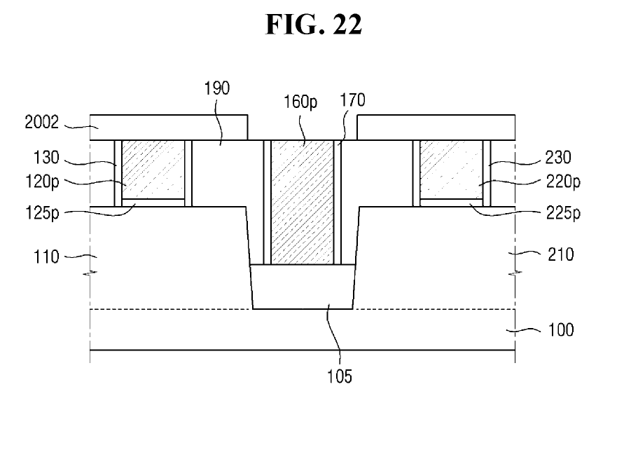

Referring to FIG. 22, a second mask pattern 2002 may be formed, which covers the upper surface of the first dummy gate electrode 120p and the upper surface of the second dummy gate electrode 220p, while exposing the upper surface of the third dummy gate electrode 106p.

The second mask pattern 2002 may include an opening which exposes the upper surface of the third dummy gate electrode 160p.

The upper surface of the third dummy gate electrode 160p and the upper surface of the first liner 170 may be exposed by the opening included in the second mask pattern 2002, but example embodiments are not limited thereto. Alternatively, the second mask pattern 2002 may expose the upper surface of the third dummy gate electrode 160p, while not exposing the first liner 170.

In describing a method for fabricating a semiconductor device according to an example embodiment, it is assumed that the width of the opening that exposes the upper surface of the third dummy gate electrode 160p is greater than the width of the third dummy gate electrode 160p.

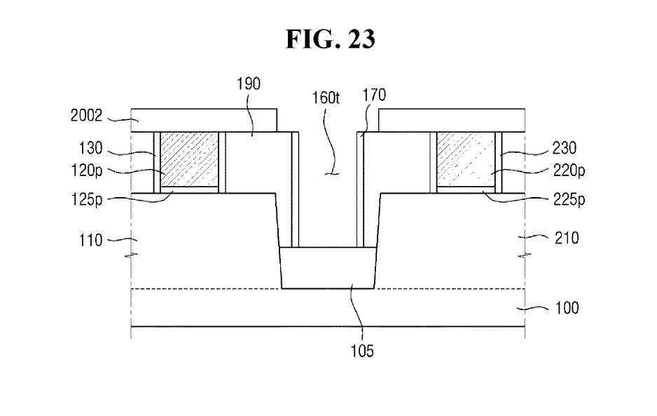

Referring to FIG. 23, the third dummy gate electrode 160p may be removed, using the second mask pattern 2002.

The third trench 160t may be formed in the interlayer insulating film 190 by removing the third dummy gate electrode 160p.

The upper surface of the field insulating film 105 may be exposed by removing the third dummy gate electrode 160p.

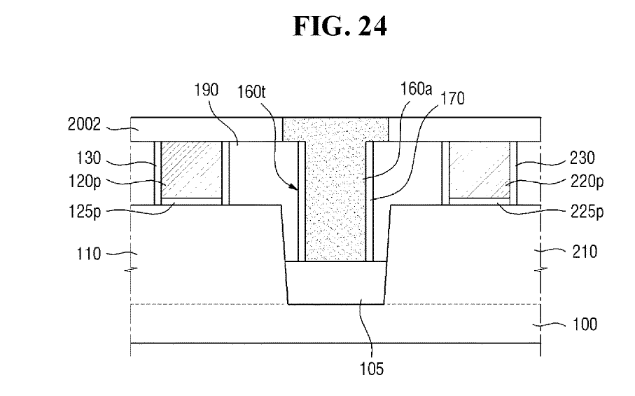

Referring to FIG. 24, a pre-insulating line pattern 160a for filling the third trench 160t may be formed on the substrate 100.

After filling the third trench 160t and forming the insulating line film that covers the upper surface of the second mask pattern 2002, the planarization process may be performed until the second mask pattern 2002 is exposed.

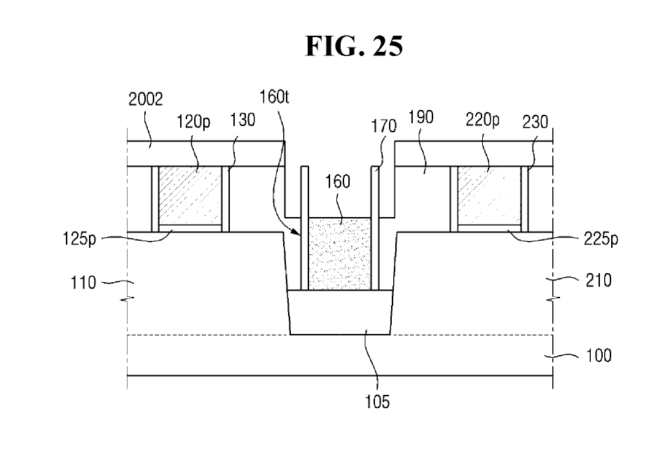

Referring to FIG. 25, the pre-insulating line pattern 160a filling the third trench 160t may be partially removed, using the second mask pattern 2002 as a mask.

The insulating line pattern 160 may be formed by partially removing the pre-insulating line pattern 160a. The insulating line pattern 160 may partially fill the third trench 160t.

In the process of forming the insulating line pattern 160, a portion of the interlayer insulating film 190 that is exposed by the opening of the second mask pattern 2002 may be removed.

However, the first liner 170 may protrude higher than the upper surface of the insulating line pattern 160, because the first liner 170 may include a material of different etch selectivity from the insulating line pattern 160.

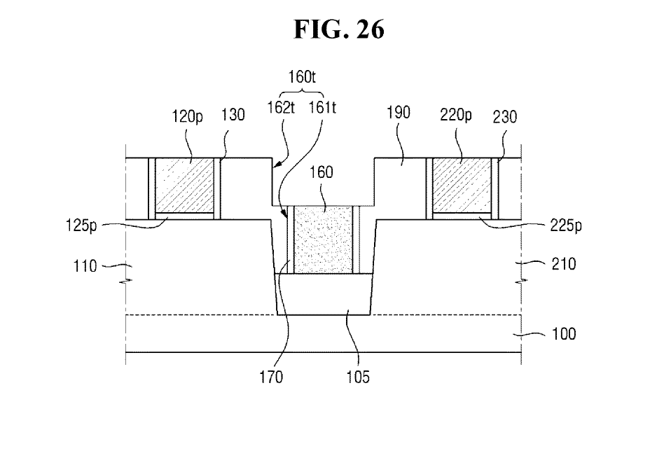

Referring to FIG. 26, the upper surface of the interlayer insulating film 190 may be exposed by removing the second mask pattern 2002.

The removal of the second mask pattern 2002 may expose the upper surface of the first dummy gate electrode 120p and the upper surface of the second dummy gate electrode 220p.

During removal of the second mask pattern 2002, at least a portion of the first liner 170 that protrudes higher than the upper surface of the insulating line pattern 160 may be removed together with the second mask pattern 2002.

As illustrated in FIG. 26, the uppermost portion of the first liner 170 and the upper surface of the insulating line pattern 160 may be in the same plane, but this is provided only for convenience of explanation and the example embodiments are not limited thereto.

The interlayer insulating film 190 may include the third trench 160t including the lower portion 161t of the third trench filled with the insulating line pattern 160 and the upper portion 162t of the third trench where the insulating line pattern 160 is not formed.

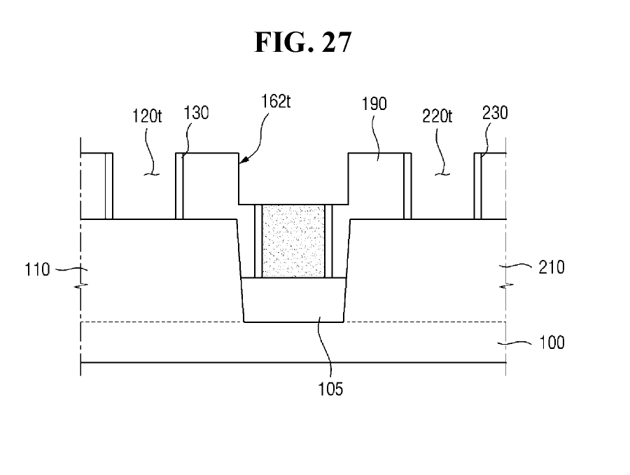

Referring to FIG. 27, with the upper surface of the insulating line pattern 160 being exposed, the first dummy gate electrode 120p and the second dummy gate electrode 220p may be removed.

Additionally, the first dummy gate insulating film 125p and the second dummy gate insulating film 225p may be removed.

The removal of the first dummy gate electrode 120p and the first dummy gate insulating film 125p may allow the first trench 120t for exposing the first fin-type pattern 110 to be formed within the interlayer insulating film 190.

The removal of the second dummy gate electrode 220p and the second dummy gate insulating film 225p may allow the second trench 220t for exposing the second fin-type pattern 210 to be formed within the interlayer insulating film 190.

Referring to FIG. 8, the first gate electrode 120 for filling the first trench 120t may be formed on the first fin-type pattern 110, and the second gate electrode 220 for filling the second trench 220t may be formed on the second fin-type pattern 210.

Further, the conductive pattern 180 for filling a portion of the third trench 160t, i.e., for filling the upper portion 162t of the third trench may be formed on the insulating line pattern 160.

Hereinbelow, a method for fabricating a semiconductor device according to another example embodiment will be explained with reference to FIGS. 10, 17 to 23, and 28 to 30.

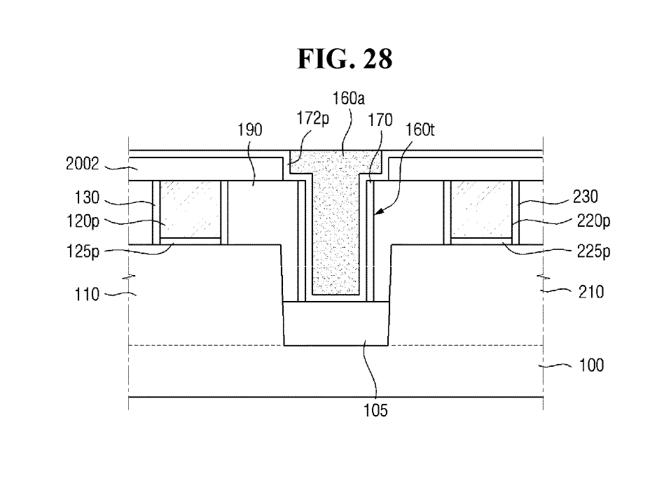

FIGS. 28 to 30 are views illustrating intermediate stages of fabrication, which is provided to explain a method for fabricating a semiconductor device according to another example embodiment. For reference, FIG. 28 may involve a process performed after FIG. 23.

Referring to FIG. 28, a liner film 172p may be formed along the sidewall and the bottom surface of the third trench 160t, and along the upper surface of the second mask pattern 2002.

After the liner film 172p is formed, the pre-insulating line pattern 160a for filling the third trench 160t may be formed.

After filling the third trench 160t and forming the insulating line film that covers the upper surface of the second mask pattern 2002, the planarization process may be performed until the liner film 172p is exposed.

The liner film 172p may include a material of different etch selectivity from the pre-insulating line pattern 160a.

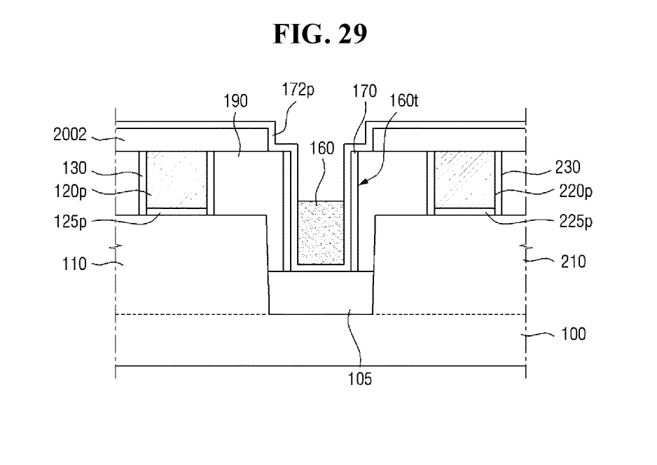

Referring to FIG. 29, the pre-insulating line pattern 160a filling the third trench 160t may be partially removed, using the second mask pattern 2002 as a mask.

The insulating line pattern 160 may be formed by partially removing the pre-insulating line pattern 160a. The insulating line pattern 160 may partially fill the third trench 160t.

The liner film 172p may cover the upper surface of the interlayer insulating film 190 which is overlapped with the opening of the second mask pattern 2002, in which case the interlayer insulating film 190 may not be removed.

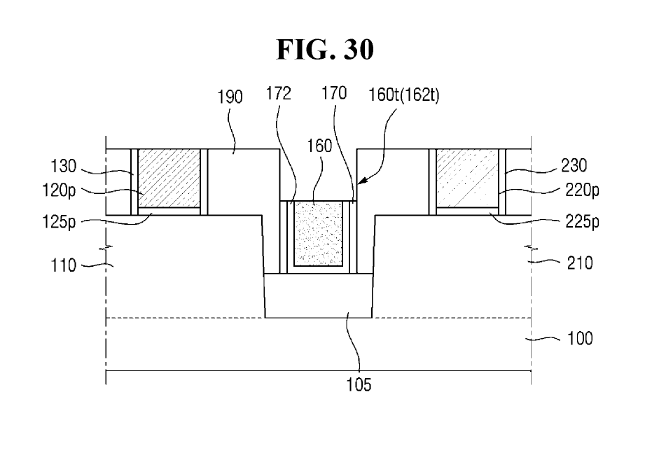

Referring to FIG. 30, with the removal of the liner film 172a and the second mask pattern 2002 formed on the upper surface of the interlayer insulating film 190, the upper surface of the interlayer insulating film 190 may be exposed.

The removal of the second mask pattern 2002 may expose the upper surface of the first dummy gate electrode 120p and the upper surface of the second dummy gate electrode 220p.

In the process of removing the second mask pattern 2002, the liner film 172a formed on the sidewall of the third trench 160t may be partially removed, and as a result, the third liner 172 may be formed.

The third liner 172 may be formed along a portion of the sidewall and the bottom surface of the third trench 160t.

Further, while the second mask pattern 2002 is removed, the first liner 170 may also be removed partially. The first liner 170 may be formed along a portion of the sidewall of the third trench 160t.

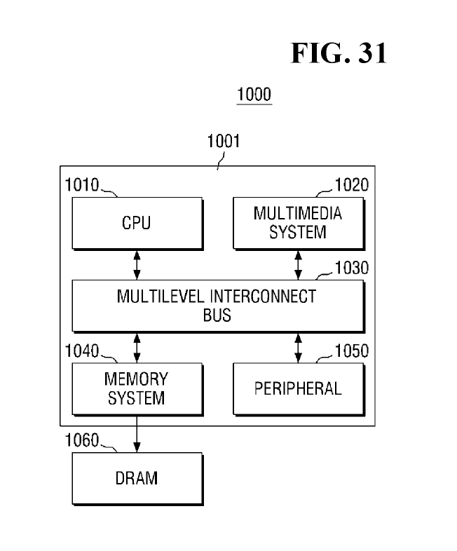

FIG. 31 is a block diagram of an example system-on-chip (SoC) system comprising a semiconductor device according to example embodiments.

Referring to FIG. 31, the SoC system 1000 includes an application processor 1001 and a dynamic random-access memory (DRAM) 1060.

The application processor 1001 may include a central processing unit (CPU) 1010, a multimedia system 1020, a bus 1030, a memory system 1040 and a peripheral circuit 1050.

The CPU 1010 may perform an arithmetic operation necessary for driving of the SoC system 1000. In some example embodiments, the CPU 1010 may be configured on a multi-core environment which includes a plurality of cores.

The multimedia system 1020 may be used for performing a variety of multimedia functions on the SoC system 1000. The multimedia system 1020 may include a three-dimensional (3D) engine module, a video codec, a display system, a camera system, or a post-processor.

The bus 1030 may be used for exchanging data communication among the CPU 1010, the multimedia system 1020, the memory system 1040 and the peripheral circuit 1050. In some example embodiments, the bus 1030 may have a multi-layer structure. Specifically, an example of the bus 1030 may be a multi-layer advanced high-performance bus (AHB), or a multi-layer advanced eXtensible interface (AXI), although example embodiments are not limited herein.

The memory system 1040 may provide environments necessary for the application processor 1001 to connect to an external memory (e.g., DRAM 1060) and perform high-speed operation. In some example embodiments, the memory system 1040 may include a separate controller (e.g., DRAM controller) to control an external memory (e.g., DRAM 1060).

The peripheral circuit 1050 may provide environments necessary for the SoC system 1000 to have a smooth connection to an external device (e.g., main board). Accordingly, the peripheral circuit 1050 may include a variety of interfaces to allow a compatible operation with the external device connected to the SoC system 1000.

The DRAM 1060 may function as an operation memory necessary for the operation of the application processor 1001. In some example embodiments, the DRAM 1060 may be arranged externally to the application processor 1001, as illustrated. Specifically, the DRAM 1060 may be packaged into a package-on-package (PoP) type with the application processor 1001.

At least one of the above-mentioned components of the SoC system 1000 may include at least one of the semiconductor devices according to the example embodiments explained above.

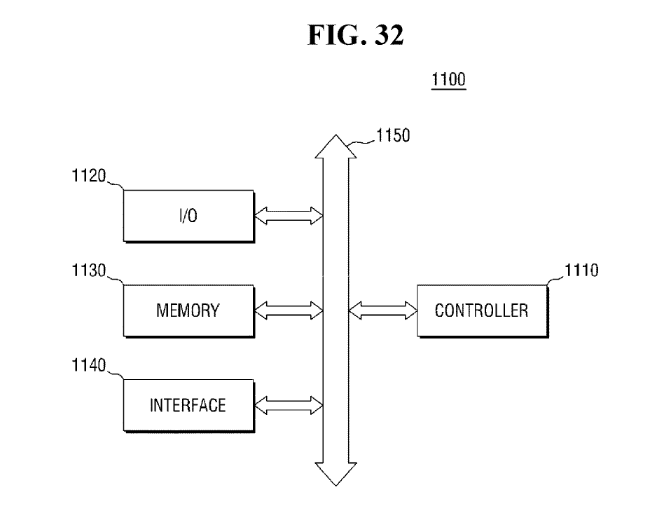

FIG. 32 is a block diagram of an electronic system comprising a semiconductor device according to example embodiments.

Referring to FIG. 32, the electronic system 1100 according to an example embodiment may include a controller 1110, an input/output (I/O) device 1120, a memory device 1130, an interface 1140 and a bus 1150. The controller 1110, the I/O device 1120, the memory device 1130 and/or the interface 1140 may be coupled with one another via the bus 1150. The bus 1150 corresponds to a path through which data travels.

The controller 1110 may include at least one of a microprocessor, a digital signal process, a micro controller and logic devices capable of performing functions similar to those mentioned above. The I/O device 1120 may include a keypad, a keyboard or a display device. The memory device 1130 may store data and/or commands. The interface 1140 may perform a function of transmitting or receiving data to or from communication networks. The interface 1140 may be wired or wireless. For example, the interface 1140 may include an antenna or a wired/wireless transceiver.

Although not illustrated, the electronic system 1100 may additionally include an operation memory configured to enhance operation of the controller 1110, such as a high-speed dynamic random-access memory (DRAM) and/or a static random access memory (SRAM).

According to the example embodiments described above, the semiconductor device may be provided within the memory device 1130, or provided as a part of the controller 1110 or the I/O device 1120.

The electronic system 1100 is applicable to a personal digital assistant (PDA) portable computer, a web tablet, a wireless phone, a mobile phone, a digital music player, a memory card, or almost all electronic products that are capable of transmitting and/or receiving data in wireless environment.

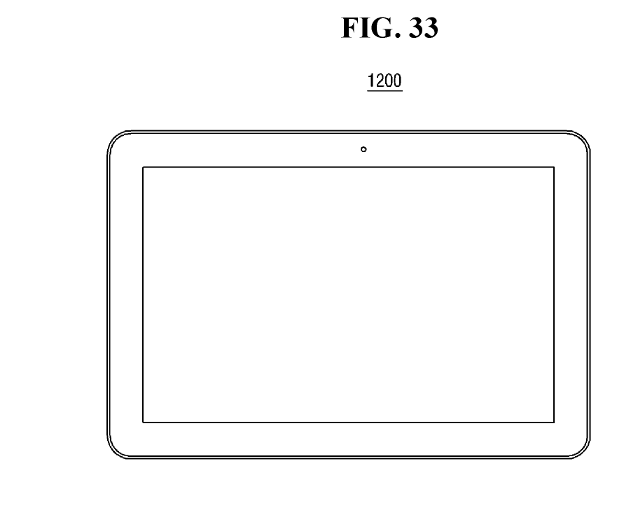

FIGS. 33 to 35 illustrate example semiconductor systems which may apply therein a semiconductor device according to example embodiments.

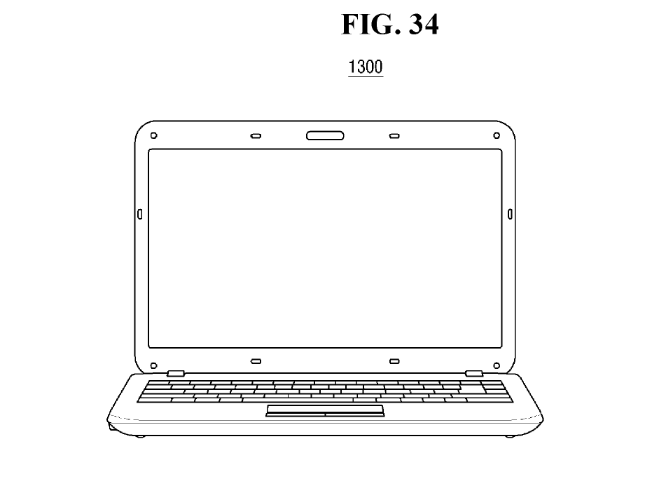

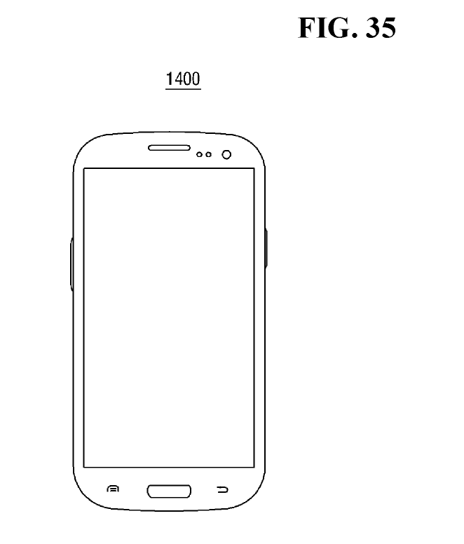

FIG. 33 illustrates a tablet personal computer (PC) 1200, FIG. 34 illustrates a laptop computer 1300, and FIG. 35 illustrates a smartphone 1400. According to the example embodiments explained above, the semiconductor device may be used in these devices, i.e., in the tablet PC 1200, the laptop computer 1300 or the smartphone 1400.

Further, it is apparent to those skilled in the art that the semiconductor device according to example embodiments is applicable to another integrated circuit device not illustrated herein.

In some embodiments, while the tablet PC 1200, the laptop computer 1300 and the smartphone 1400 are exemplified herein as a semiconductor system according to the example embodiments, the example embodiments of the semiconductor system are not limited to any of the examples given above.

In some example embodiments, the semiconductor system may be realized as a computer, a ultra mobile PC (UMPC), a workstation, a net-book, personal digital assistants (PDA), a portable computer, a wireless phone, a mobile phone, an e-book, a portable multimedia player (PMP), a portable game player, a navigation device, a black box, a digital camera, a three-dimensional television, a digital audio recorder, a digital audio player, a digital picture recorder, a digital picture player, a digital video recorder, or a digital video player.

The embodiments of the present disclosure have been described with reference to the attached drawings, but it may be understood by one of ordinary skill in the art that the disclosed embodiments may be performed one of ordinary skill in the art in other specific forms without changing the technical concept or essential features of the disclosed concepts. Further, the above-described embodiments are merely examples and do not limit the scope of the rights of the inventive concepts.

What is claimed is:

1. A semiconductor device, comprising:
a first fin-type pattern and a second fin-type pattern;
a first trench formed between the first fin-type pattern and the second fin-type pattern;
a field insulating film partially filling the first trench, an upper surface of the field insulating film being lower than an upper surface of the first fin-type pattern and lower than an upper surface of the second fin-type pattern;
an interlayer insulating film formed on the field insulating film, the interlayer insulating film covering the first fin-type pattern and the second fin-type pattern, the interlayer insulating film comprising a second trench exposing the upper surface of the field insulating film, the second trench comprising an upper portion and a lower portion;
an insulating line pattern filling the lower portion of the second trench; and
a conductive pattern filling the upper portion of the second trench.

2. The semiconductor device of claim 1, wherein a bottom surface of the conductive pattern is higher than the upper surface of the first fin-type pattern and higher than the upper surface of the second fin-type pattern.

3. The semiconductor device of claim 1, wherein the insulating line pattern contacts the field insulating film.

4. The semiconductor device of claim 1, further comprising a liner formed between the interlayer insulating film and the insulating line pattern.

5. The semiconductor device of claim 4, wherein the liner extends along a sidewall of the lower portion of the second trench.

6. The semiconductor device of claim 1, further comprising a liner formed along the upper surface of the field insulating film, between the insulating line pattern and the field insulating film.

7. The semiconductor device of claim 6, wherein the liner comprises a first portion formed along a bottom surface of the insulating line pattern and a second portion formed along a sidewall of the insulating line pattern.

8. The semiconductor device of claim 7, wherein a thickness of the first portion of the liner is less than a thickness of the second portion of the liner.

9. The semiconductor device of claim 1, further comprising a liner formed along an upper surface of the insulating line pattern and a sidewall of the upper portion of the second trench.

10. The semiconductor device of claim 1, further comprising a first gate electrode formed on the first fin-type pattern, and a second gate electrode formed on the second fin-type pattern,
wherein an upper surface of the first gate electrode, an upper surface of the second gate electrode, and an upper surface of the conductive pattern are located in the same plane.

11. The semiconductor device of claim 1, wherein the insulating line pattern does not contact the first fin-type pattern and the second fin-type pattern.

12. A semiconductor device, comprising:
a first fin-type pattern and a second fin-type pattern;
a trench formed between the first fin-type pattern and the second fin-type pattern;
a field insulating film partially filling the trench;
an insulating line pattern formed on the field insulating film, and formed between the first fin-type pattern and the second fin-type pattern; and
a conductive pattern formed on the insulating line pattern, and formed between the first fin-type pattern and the second fin-type pattern,
wherein a bottom surface of the conductive pattern is higher than an upper surface of the first fin-type pattern and higher than an upper surface of the second fin-type pattern, and
wherein the insulating line pattern does not contact the first fin-type pattern and the second fin-type pattern.

13. The semiconductor device of claim 12, further comprising a liner formed along a sidewall and a bottom surface of the insulating line pattern,
wherein a thickness of the liner at the sidewall of the insulating line pattern is greater than a thickness of the liner at the bottom surface of the insulating line pattern.

14. The semiconductor device of claim 12, further comprising a first gate electrode formed on the first fin-type pattern, and a second gate electrode formed on the second fin-type pattern,
wherein a height of the first gate electrode is greater than a height of the conductive pattern, and a height of the second gate electrode is greater than the height of the conductive pattern.

15. The semiconductor device of claim 12, further comprising a liner formed along a sidewall and a bottom surface of the conductive pattern.

16. A semiconductor device, comprising:
a first fin-type pattern and a second fin-type pattern;
a field insulating film partially surrounding the first fin-type pattern and the second fin-type pattern; and
a gate pattern formed on the field insulating pattern, on the first fin-type pattern, and on the second fin-type pattern,
wherein the gate pattern comprises a first gate electrode intersecting the first fin-type pattern, a second gate electrode intersecting the second fin-type pattern, and a connect pattern connecting the first gate electrode and the second gate electrode, and
wherein the connect pattern comprises an insulating line pattern formed on the field insulating film and a conductive pattern formed on the insulating line pattern.

17. The semiconductor device of claim 16, further comprising a liner formed along a sidewall and a bottom surface of the insulating line pattern.

18. The semiconductor device of claim 17, wherein the liner does not extend between the conductive pattern and the first gate electrode, and does not extend between the conductive pattern and the second gate electrode.

19. The semiconductor device of claim 17, wherein the liner does not extend between the first gate electrode and the field insulating film, and does not extend between the second gate electrode and the field insulating film.

20. The semiconductor device of claim 16, further comprising a high-k gate insulating film formed along the first fin-type pattern and the second fin-type pattern.
